(19) United States
(12) Patent Application Publication
(10) Pub. No.: US 2025/0113517 A1
(43) Pub. Date: Apr. 3, 2025

(54) EPITAXIAL REGIONS IN SEMICONDUCTOR DEVICES

(71) Applicant: Taiwan Semiconductor Manufacturing Co., Ltd., Hsinchu (TW)

(72) Inventors: Shao-An WANG, Hsinchu County (TW); Ding-Kang SHIH, New Taipei City (TW); Chia-Ling PAI, Taichung City (TW); Pinyen LIN, Rochester, NY (US)

(73) Assignee: Taiwan Semiconductor Manufacturing Co., Ltd., Hsinchu (TW)

(21) Appl. No.: 18/477,648

(22) Filed: Sep. 29, 2023

(51) Int. Cl. H01L 29/66; H01L 21/02; H01L 21/3065; H01L 21/8238; H01L 27/092; H01L 29/06; H01L 29/423; H01L 29/775; H01L 29/786

(52) U.S. Cl. CPC H10D 30/024; H01L 21/0262; H01L 21/3065; H10D 84/017; H10D 84/038; H10D 30/43; H10D 30/6735; H10D 30/6757; H10D 62/121; H10D 84/85

(57) ABSTRACT

A method of forming source/drain regions of semiconductor devices is disclosed. The method includes forming a fin structure on a substrate, forming a polysilicon structure on the fin structure, removing a portion of the fin structure adjacent to the polysilicon structure to form an opening, and forming a S/D region in the opening. The forming the S/D region includes exposing the fin structure in the opening to a first flow rate of a precursor gas during a first phase of a gas flow cycle, a second flow rate of the precursor gas during a second phase of the gas flow cycle. The exposing the fin structure in the opening to the precursor gas, the etching gas, and the plasma is performed in an in-situ process.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), gate-all-around field effect transistors (GAA FETs), complementary field effect transistors (CFETs), and vertical field effect transistors (VFETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a finFET, in accordance with some embodiments.

FIGS. 1B and 1C illustrate different cross-sectional views of a finFET, in accordance with some embodiments.

FIG. 2 is a flow diagram of a method for fabricating a finFET, in accordance with some embodiments.

FIG. 3 illustrates an isometric view of a finFET at a stage of its fabrication process, in accordance with some embodiments.

FIGS. 4A-8B, 11A-12B, and 15A-16B illustrate cross-sectional views of a finFET at various stages of its fabrication process, in accordance with some embodiments.

FIGS. 9A-10B and 13A-14B illustrate graphical representations of epitaxial processes for the formation of source/drain (S/D) regions in a semiconductor device, in accordance with some embodiments.

FIG. 17A illustrates an isometric view of a CFET, in accordance with some embodiments.

FIG. 17B illustrates a cross-sectional view of a CFET, in accordance with some embodiments.

FIG. 18 is a flow diagram of a method for fabricating a CFET, in accordance with some embodiments.

FIG. 19 illustrates an isometric view of a CFET at a stage of its fabrication process, in accordance with some embodiments.

FIGS. 20-33 illustrate cross-sectional views of a CFET at various stages of its fabrication process, in accordance with some embodiments.

FIG. 34A illustrates an isometric view of a VFET, in accordance with some embodiments.

FIG. 34B illustrates a cross-sectional view of a VFET, in accordance with some embodiments.

FIG. 35 is a flow diagram of a method for fabricating a VFET, in accordance with some embodiments.

FIGS. 36-45 illustrate cross-sectional views of a VFET at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

Source/drain (S/D) regions of field effect transistors, such as finFETs, CFETs, or VFETs can be formed by epitaxially growing monocrystalline semiconductor materials in openings on a substrate. Due to the increasing demand of scaling down the dimensions of semiconductor devices, critical dimension (CD) of openings are decreasing below about 30 nm, requiring the S/D regions to be formed in openings with increasing aspect ratios (ARs) (e.g., AR greater than about 5).

However, epitaxially growing monocrystalline semiconductor materials in openings having dielectric side surfaces may also be accompanied by the formation of amorphous semiconductor materials on dielectric side surfaces. With ARs of the openings increasing, amorphous semiconductor materials formed on dielectric side surfaces can result in nodules and clogs, which can degrade properties of the S/D regions, such as increase the resistivity of the S/D regions. Accordingly, methods of forming the S/D regions can include etching or removing the amorphous semiconductor materials from the dielectric side surfaces along with epitaxially growing the monocrystalline semiconductor materials. One of the challenges of etching or removing the amorphous semiconductor materials from the dielectric side surfaces is achieving a high etch selectivity at low temperatures, that is achieving a high ratio between the etching rates of the amorphous semiconductor material and the crystalline semiconductor material at low temperatures. The method of epitaxially growing semiconductor materials using a thermal chemical vapor deposition (CVD) process suffers etch selectivity loss at temperatures below about 500° C., and requires additional ex-situ etching processes to remove the nodules or clogs from the dielectric side surfaces.

To address the abovementioned challenges, the present disclosure provides example methods of forming S/D regions or epitaxial regions in FETs (e.g., finFETs, CFETs, or VFETs) using a plasma-enhanced chemical vapor deposition (PECVD) process at a temperature of about 500° C. or below, with etch selectivity of etching processes greater than about 6. In some embodiments, the method can include a deposition process and an etching process performed in-situ in a PECVD chamber. In some embodiments, the method can include providing a plasma, an etching gas, and a precursor gas in the PECVD chamber during the deposition and/or the etching process to form undoped S/D regions. In some embodiments, the method can further include providing a dopant precursor gas in the PECVD chamber during the deposition and/or the etching process to form p-type or n-type S/D regions.

In some embodiments, the plasma can form radicals of the precursor gas and/or the etching gas during the deposition process and/or the etching process. And, as the radicals are highly reactive, the use of plasma can increase the deposition rate and/or the etching rate during the deposition process and/or the etching process at low temperatures (e.g., at a temperature of about 500° C. to about 20° C., at a temperature of about 400° C. or below, or at a temperature of about 400° C. to about 20° C.). Also, due to the highly reactive radicals of the etching gas, additional ex-situ etching processes can be eliminated from the fabrication process of S/D regions or epitaxial regions in the FETs. Thus, the use of plasma during the deposition process and/or the etching process can decrease the time and cost of fabricating the S/D regions or epitaxial regions in the FETs.

In some embodiments, a plasma condition, a flow rate of the etching gas, a flow rate of the precursor gas, and/or a flow rate of the dopant precursor gas can be controlled to selectively grow semiconductor materials of monocrystalline form in openings with CD less than about 30 nm and AR greater than about 5, while adequately preventing the formation of defective amorphous semiconductor regions in the S/D regions or epitaxial regions and the formation of nodules and clogs on side surfaces of dielectric layers adjacent to the S/D regions or epitaxial regions in the FETs. Thus, the S/D regions or epitaxial regions formed in the FETs by the example methods can be formed with improved qualities, such as lower resistivity at lower temperatures compared to S/D regions or epitaxial regions formed by other epitaxial processes.

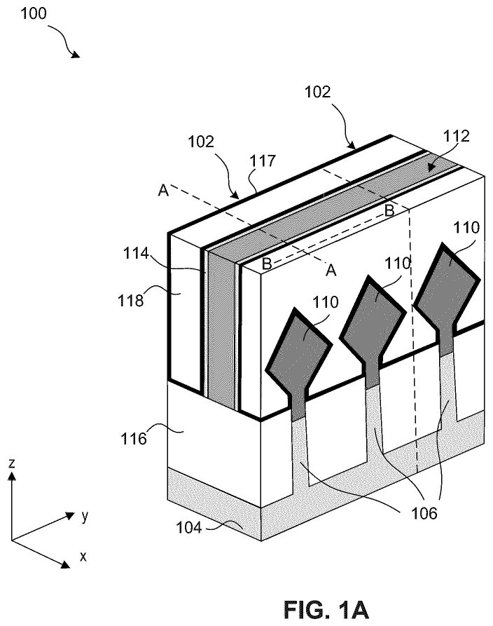

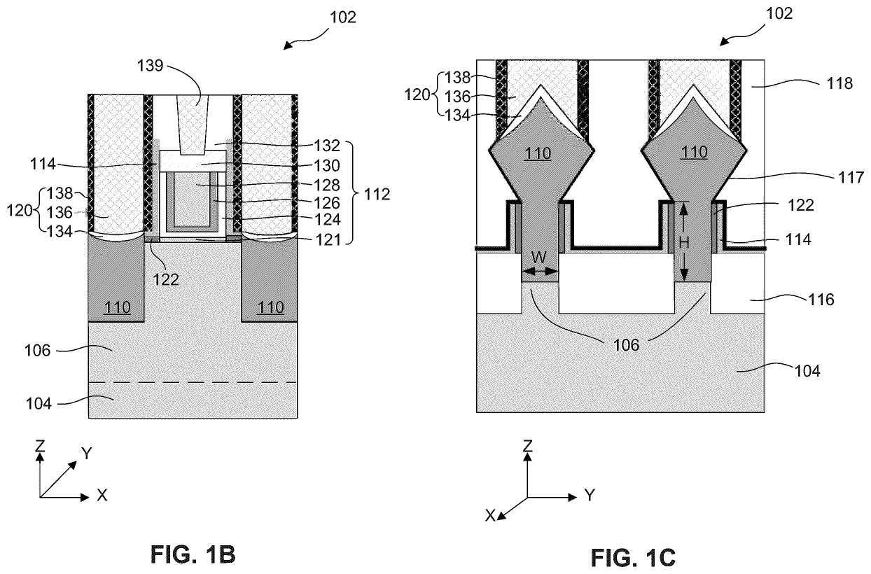

FIG. 1A illustrates an isometric view of a semiconductor device 100 including one or more FETs 102, according to some embodiments. FIG. 1B illustrates a cross-sectional view of FET 102 along line A-A of FIG. 1A, according to some embodiments. FIG. 1C illustrates a cross-sectional view of FET 102 along line B-B of FIG. 1A, according to some embodiments. FIGS. 1B and 1C illustrate cross-sectional views of FET 102 with additional structures that are not shown in FIG. 1A for simplicity. The discussion of elements with the same annotations applies to each other, unless mentioned otherwise. In some embodiments, FET 102 can represent an n-type finFET (“NFET 102”) or a p-type finFET 102 (“PFET 102”) and the discussion of FET 102 applies to both NFET 102 and PFET 102, unless mentioned otherwise. In some embodiments, FET 102 can represent a gate-all-around (GAA) transistor, a nano-sheet transistor, a 2D material transistor, a planar transistor, a back-end-of-line (BEOL) transistor, a NAND transistor, a 3D NAND transistor, an NMOS transistor, or a PMOS transistor. In some embodiments, FET 102 can be electrically connected to other devices not shown in FIGS. 1A-1C. For example, FET 102 can be electrically connected to a passive device (such as an inductor, a capacitor, and/or a resistor), an amplifier, a filter, a memory, or a combination thereof.

Referring to FIGS. 1A-1C, in some embodiments, FET 102 can be a finFET, such as FET 102 in FIGS. 1B and 1C. In some embodiments, FET 102 can include (i) a substrate 104, (ii) fin structures 106 disposed on substrate 104, (iii) a gate structure 112 disposed on fin structures 106, (iv) gate spacers 114 disposed along sidewalls of gate structure 112, (v) a thermal oxide layer 122 disposed on fin structures 106 and under gate spacers 114, (vi) S/D regions 110 disposed in portions of fin structures 106 that are not covered by gate structure 112, (vii) S/D contact structures 120 disposed on S/D regions 110, and (viii) a gate contact structure 139 disposed on gate structure 112. In some embodiments, fin structures 106, and gate structure 112 are electrically active and can be electrically coupled to power supplies (not shown) through contact structures, such as S/D contact structures 120 and gate contact structure 139. S/D regions 110 may refer to a source or a drain, individually or collectively dependent upon the context.

FET 102 can be formed on substrate 104. There may be other FETs and/or structures (e.g., isolation structures) formed on substrate 104. Substrate 104 can be a semiconductor material, such as silicon (Si), germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). In some embodiments, a top surface of substrate 104 can be normal to [100] or [110] crystallographic orientation. In some embodiments, fin structures 106 can include a material similar to substrate 104 and can have elongated sides extending along an X-axis. In some embodiments, thermal oxide layer 122 can be disposed on fin structures 106.

FET 102 can further include shallow trench isolation (STI) regions 116, an etch stop layer (ESL) 117, and an interlayer dielectric (ILD) layer 118. ILD layer 118 can be disposed on ESL 117. ESL 117 can be configured to protect gate structure 112 and/or S/D regions 110. In some embodiments, STI regions 116, ESL 117, and ILD layer 118 can include an insulating material, such as silicon oxide (SiO₂), silicon nitride (SiN), silicon carbon nitride (SiCN), silicon oxycarbon nitride (SiOCN), and silicon germanium oxide (SiGeOₓ).

Referring to FIG. 1B, gate structure 112 can be multi-layered structures. In some embodiments, gate structure 112 can include i) an interfacial oxide layer 121 disposed on fin structures 106; ii) a gate oxide layer 124 disposed on interfacial oxide layer 121; iii) a work function metal (WFM) layer 126 disposed on gate oxide layer 124; iv) a gate metal fill layer 128 disposed on WFM layer 126; v) a conductive capping layer 130 disposed on gate oxide layer 124, WFM layer 126, and gate metal fill layer 128; and vi) an insulating capping layer 132 disposed on conductive capping layer 130. In some embodiments, the stack of WFM layer 126 and gate metal fill layer 128 of gate structure 112 can be referred to as a “metal gate stack” of gate structure 112.

In some embodiments, interfacial oxide layer 121 can include a thermal oxide layer. That is, interfacial oxide layer 121 is formed by thermally oxidizing the portion of fin structures 106 under gate structure 112. In some embodiments, gate oxide layer 124 can include a non-thermal oxide layer. That is, gate oxide layer 124 is not formed by thermally oxidizing the portion of fin structures 106 under gate structure 112. In some embodiments, gate oxide layer 124 can include a high-k dielectric material, such as hafnium oxide (HfO₂), titanium oxide (TiO₂), hafnium zirconium oxide (HfZrO), tantalum oxide (Ta₂O₃), zirconium oxide (ZrO₂), and zirconium silicate (ZrSiO₂).

In some embodiments, gate structure 112 can represent an NFET gate structure (NFET gate structure 112) or a PFET gate structure (PFET gate structure 112). In some embodiments, WFM layer 126 of NFET gate structure 112 can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, other suitable Al-based materials, or a combination thereof. In some embodiments, WFM layer 126 of PFET gate structure 112 can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, tantalum copper (Ta—Cu), and a combination thereof. In some embodiments, gate metal fill layer 128 can include a suitable conductive material, such as tungsten (W), Ti, silver (Ag), ruthenium (Ru), molybdenum (Mo), copper (Cu), cobalt (Co), Al, iridium (Ir), nickel (Ni), metal alloys, and a combination thereof.

Insulating capping layer 132 protect the underlying conductive capping layer 130 from structural and/or compositional degradation during subsequent processing of the semiconductor device. In some embodiments, insulating capping layer 132 can include a nitride material, such as silicon nitride, and can have a thickness of about 5 nm to about 10 nm for adequate protection of the underlying conductive capping layer 130. Conductive capping layer 130 provides conductive an interface between gate contact structure 139 and gate metal fill layer 128 to electrically connect the metal gate stack of gate structure 112 to gate contact structure 139 without forming gate contact structure 139 directly on or within the metal gate stacks. Gate contact structure 139 is not formed directly on or within the metal gate stacks to prevent contamination of the metal gate stacks by any of the processing materials used in the formation of gate contact structure 139. Contamination of the metal gate stack can lead to the degradation of device performance. Thus, with the use of conductive capping layer 130, the metal gate stack can be electrically connected to gate contact structures 139 without compromising the integrity of gate structure 112. In some embodiments, conductive capping layer 130 and gate contact structure 139 can include a metallic material, such as W, Ru, Ir, Mo, other suitable metallic materials, and a combination thereof. In some embodiments, conductive capping layer 130 and gate contact structure 139 can include the same metallic material or can have metallic materials different from each other.

In some embodiments, gate spacer 114 can be include a vertical portion disposed directly on sidewalls of gate structure 112. In some embodiments, gate spacer 114 can include a horizontal portion in contact with thermal oxide layer 122. In some embodiments, a top surface of gate spacer 114 can be above a top surface of conductive capping layer 130 and below a top surface of insulating capping layer 132. In some embodiments, the top surface of gate spacer 114 can be covered by insulating capping layer 132. In some embodiments, gate spacer 114 can include a silicon oxycarbide (SiCO) layer, a silicon carbon oxynitride (SiCON) layer, a silicon nitride (SiN) layer, or a combination thereof. In some embodiments, gate spacer 114 can have a thickness of about 2 nm to about 10 nm.

In some embodiments, S/D regions 110 can be disposed on recessed portions of fin structures 106, as shown in FIGS. 1B and 1C. In some embodiments, S/D regions 110 can be in contact with a sidewall of a portion of fin structures 106 adjacent to gate structure 112. In some embodiments, S/D regions 110 can be in contact with sidewalls of STI regions 116. In some embodiments, S/D regions 110 can be in contact with side surfaces of thermal oxide layer 122. In some embodiments, a width W of S/D regions 110 between opposite sidewalls of STI regions 116 can be about 5 nm to about 30 nm, as shown in FIG. 1C. Width W is also referred to as critical dimension (CD). A height H of portions of S/D regions 110 below a top surface of thermal oxide layer 122 is indicated in FIG. 1C. A ratio between height H and width W is referred to as an aspect ratio (AR). In some embodiments, the AR of S/D regions 110 can be greater than about 5.

In some embodiments, each of S/D regions 110 can include an epitaxially-grown semiconductor material, such as Si, Ge, silicon carbide (SiC), SiGe, and silicon-tin (SiSn). In some embodiments, for NFET 102, each of S/D regions 110 can include an epitaxially-grown n-type semiconductor material, silicon phosphide (SiP), silicon carbon phosphide (SiCP), silicon germanium phosphide (SiGeP), silicon germanium carbon phosphide (SiGeCP), silicon arsenide (SiAs), silicon carbon arsenide (SiCAs), silicon germanium arsenide (SiGeAs), and silicon germanium carbon arsenide (SiGeCAs). In some embodiments, for PFET 102, each of S/D regions 110 can include an epitaxially-grown p-type semiconductor material, such as silicon boride (SiB), silicon carbon boride (SiCB), silicon germanium boride (SiGeB), silicon germanium carbon boride (SiGeCB). In some embodiments, dopant concentration in S/D regions 110 can be about 10¹⁹ atoms/cm³ to about 10²¹ atoms/cm³.

In some embodiments, S/D contact structures 120 can include silicide layers 134 disposed on S/D regions 110, contact plugs 136 disposed on silicide layers 134, and nitride barrier layers 138 along sidewalls of contact plugs 136. In some embodiments, silicide layers 134 can include titanium silicide (TiₓSi_{y}), tantalum silicide (TaₓSi), molybdenum silicide (MoₓSi_{y}), nickel silicide (NiₓSi_{y}), cobalt silicide (CoₓSi_{y}), tungsten silicide (WₓSi_{y}), or a combination thereof. In some embodiments, contact plugs 136 can include conductive materials, such as cobalt (Co), tungsten (W), ruthenium (Ru), iridium (Ir), nickel (Ni), osmium (Os), rhodium (Rh), aluminum (Al), molybdenum (Mo), copper (Cu), zirconium (Zr), stannum (Sn), silver (Ag), gold (Au), zinc (Zn), cadmium (Cd), and a combination thereof.

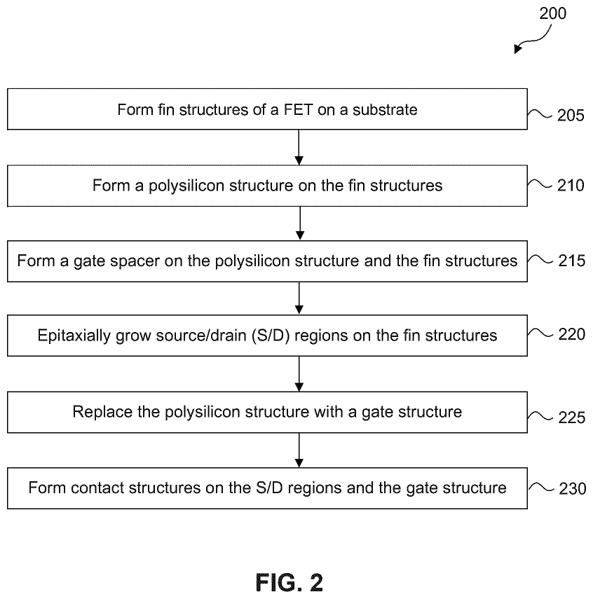

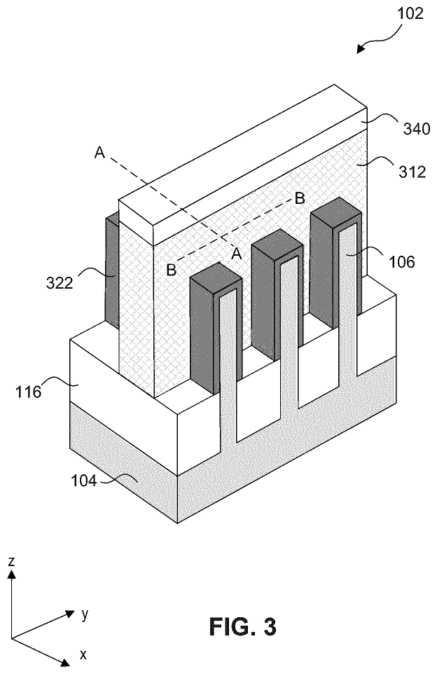

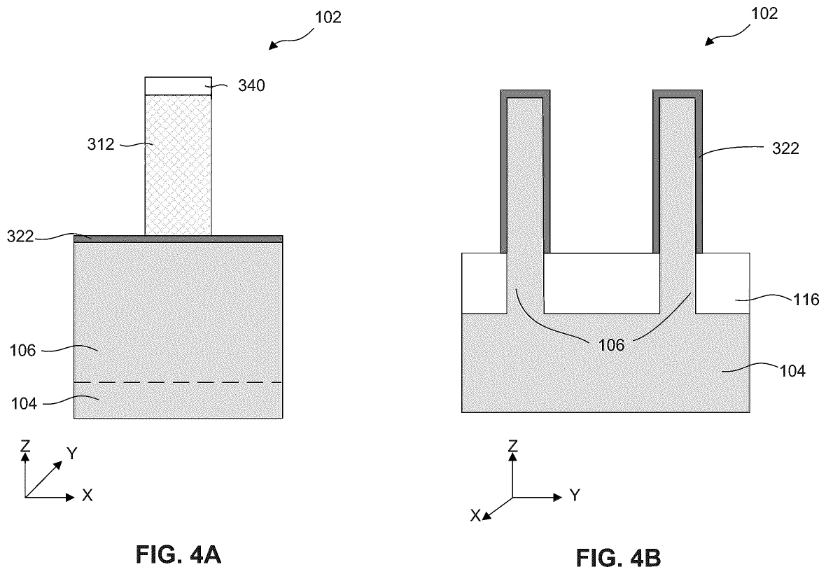

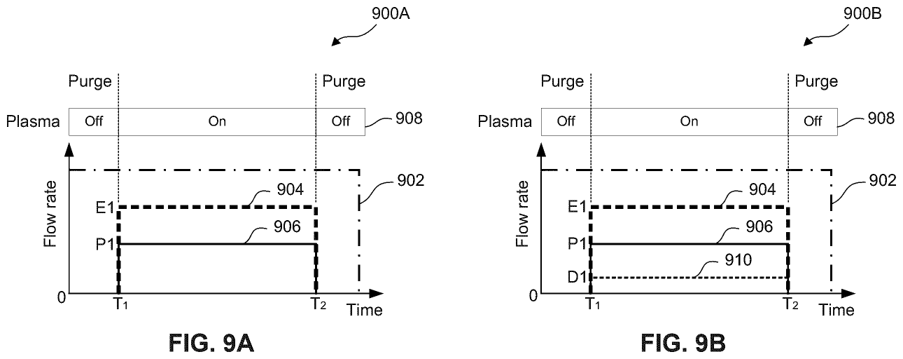

FIG. 2 is a flow diagram of an example method 200 for fabricating FET 102 with the structure shown in FIGS. 1A-1C, according to some embodiments. For illustrative purposes, the operations illustrated in FIG. 2 will be described with reference to the example fabrication process for fabricating FET 102 as illustrated in FIGS. 3 and 4A-16B. FIG. 3 is an isometric view of FET 102 at a stage of its fabrication, according to some embodiments. FIGS. 4A, 5A, 6A, 7A, 8A, 11A, 12A, 15A, and 16A are cross-sectional views of FET 102 along line A-A of FIGS. 1A and 3 at various stages of fabrication, according to some embodiments. FIGS. 4B, 5B, 6B, 7B, 8B, 11B, 12B, 15B, and 16B are cross-sectional views of FET 102 along line B-B of FIGS. 1A and 3 at various stages of fabrication, according to some embodiments. FIGS. 9A-10B and 13A-14B illustrate configurations of a plasma condition and flow rates of processing gases for epitaxially growing a semiconductor material during the formation of FET 102, according to some embodiments. Operations can be performed in a different order or not performed depending on specific applications. It should be noted that method 200 may not produce a complete FET 102. Accordingly, it is understood that additional processes can be provided before, during, and after method 200, and that some other processes may only be briefly described herein. Elements in FIGS. 3 and 4A-16B with the same annotations as elements in FIGS. 1A-1C are described above.

In operation 205, fin structures of a FET is formed on a substrate. For example, as shown in FIG. 3, fin structures 106 of FETs 102 are formed on substrate 104. The formation of fin structures 106 can include sequential operations of (i) forming a patterned masking layer (not shown) on substrate 104, and (ii) etching substrate 104 to form fin structures 106. After the formation of fin structures 106, STI regions 116 can be formed as shown in FIG. 3. After the formation of STI regions 116, a thermal oxide layer can be formed on the fin structure. For example, as shown in FIG. 3, a thermal oxide layer 322 is formed on fin structures 106. Thermal oxide layer 322 can be formed in a thermal oxidation process. In some embodiments, the thermal oxidation process can include oxidizing surfaces of fin structures 106 that are exposed above STI regions 116 in an oxidizing ambient at a temperature of about 30° C. to about 200° C. or at other suitable oxidation temperatures. In some embodiments, the oxidizing ambient can include a combination of ozone (O₃), a mixture of ammonia hydroxide, hydrogen peroxide, and water, and/or a mixture of hydrochloric acid, hydrogen peroxide, and water. In some embodiments, the thermal oxidation process can include oxidizing the surfaces of fin structures 106 that are exposed above STI regions 116 in an oxygen ambient or in a steam of oxygen ambient at a temperature of about 400° C. to about 600° C.

Referring to FIG. 2, in operation 210, a polysilicon structure is formed on the fin structures. For example, as described with reference to FIG. 3, a polysilicon structure 312 is formed on fin structures 106 and on thermal oxide layer 322. FIGS. 4A and 4B are cross-sectional views of FET 102 along line A-A and B—B of FIG. 3, respectively. Polysilicon structure 312 is a sacrificial structure and can be replaced in a subsequent replacement process to form gate structure 112. In some embodiments, hard mask layer 340 can be formed on polysilicon structure 312 to pattern polysilicon structure 312. In some embodiments, the formation of polysilicon gate structure 312 can include sequential operations of i) blanket depositing a layer of polysilicon material, ii) forming and patterning hard mask layer 340 on the layer of polysilicon material, and iii) etching the layer of polysilicon material through the patterned hard mask layer 340. In some embodiments, the blanket deposition of the layer of polysilicon material can include a chemical vapor deposition (CVD) process, a physical vapor deposition (PVD), an atomic layer deposition (ALD) process, or any other suitable deposition process. In some embodiments, etching of the deposited layer of polysilicon material can include a dry etch, a wet etch, or a combination thereof.

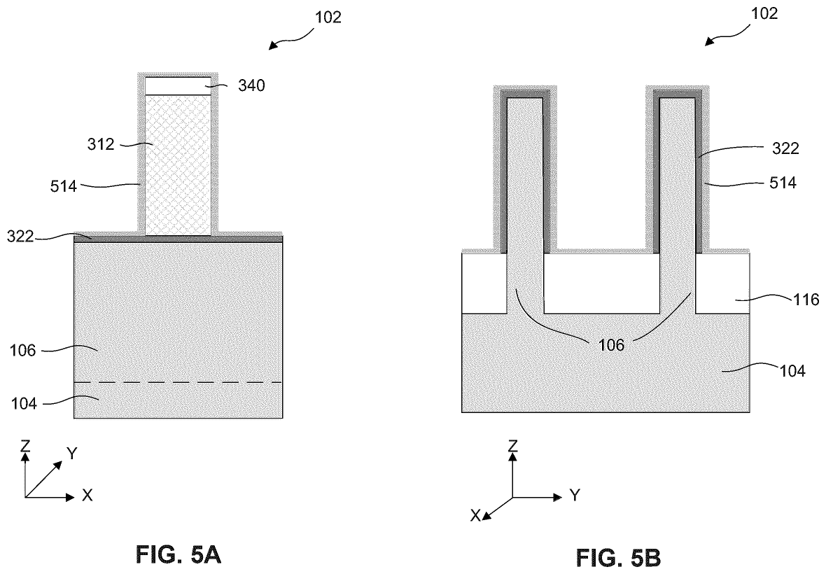

Referring to FIG. 2, in operation 215, a gate spacer is formed on the polysilicon structure and the thermal oxide layer. For example, as described with reference to FIGS. 5A and 5B, a gate spacer 514 is formed on sidewalls of polysilicon structure 312, surfaces of thermal oxide layer 322, and surfaces of STI regions 116. In some embodiments, the formation of gate spacer 514 can include blanket deposition of a layer of dielectric material on the structures of FIGS. 4A and 4B. In some embodiments, forming gate spacer 114 can include depositing the material of gate spacer 114 in a CVD process, a PVD process, an ALD process, or any other suitable deposition process.

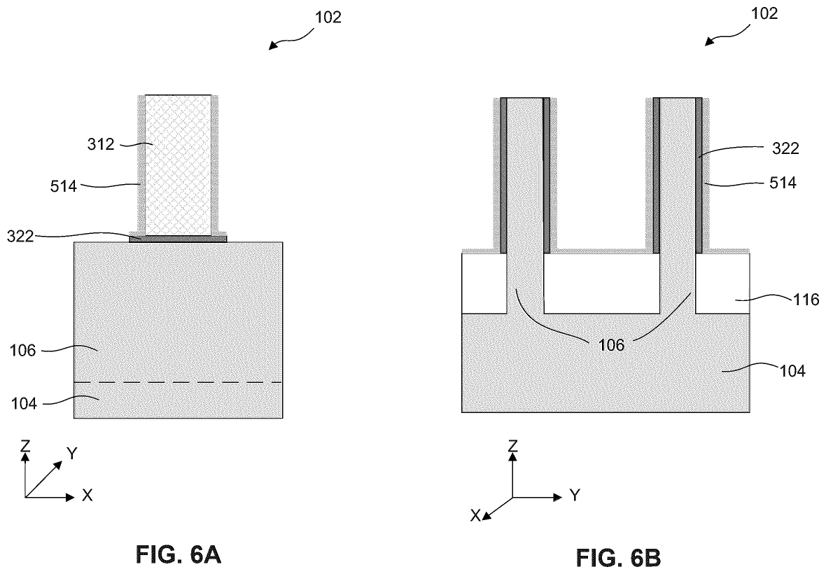

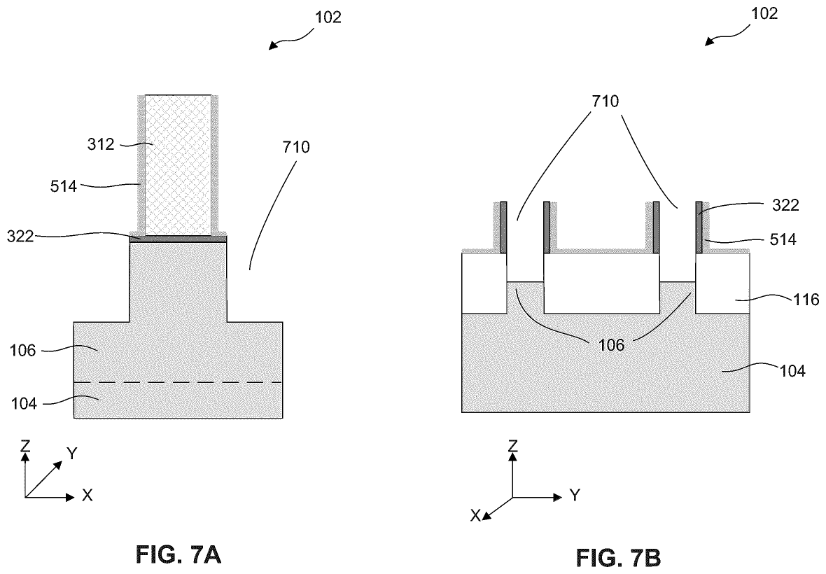

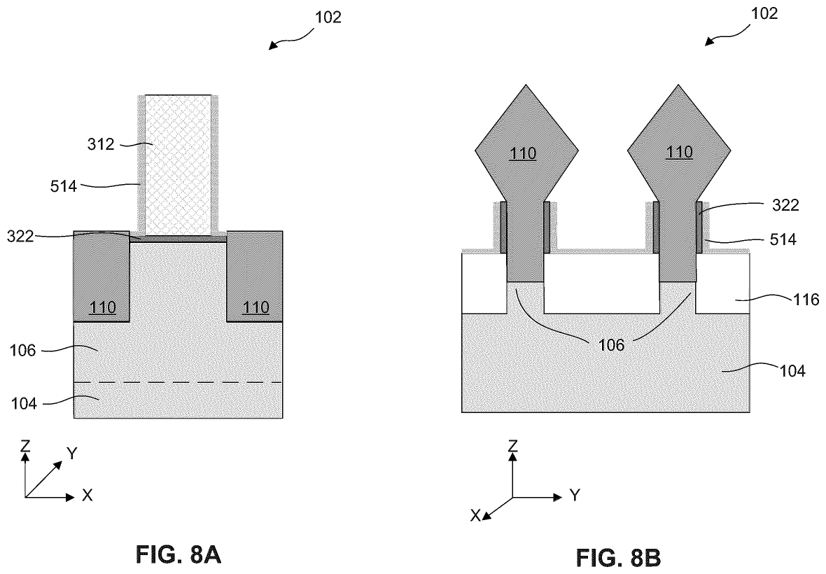

Referring to FIG. 2, in operation 220, S/D regions are formed on the fin structures. For example, as described with reference to FIGS. 6A-14B, S/D regions 110 are formed on fin structures 106. The formation of S/D regions 110 can include sequential operations of (i) removing portions of gate spacer 514 and thermal oxide layer 322 to expose regions of fin structures 106, as shown in FIGS. 6A and 6B, (ii) forming S/D openings 710 by removing portions of fin structures 106, portions of thermal oxide layer 322, and portions of gate spacer 514, as shown in FIGS. 7A and 7B, and (iii) epitaxially growing a semiconductor material in S/D openings 710 to form S/D regions 110, as shown in FIGS. 8A and 8B. In some embodiments, removing the portions of gate spacer 514 and thermal oxide layer 322 can include patterning gate spacer 514 with a mask and etching the portions of gate spacer 514 and thermal oxide layer 322 to expose regions of fin structures 106. In some embodiments, removing portions of fin structures 106 can include a dry etch, a wet etch, or a combination thereof. In some embodiments, a pre-cleaning operation can be performed before epitaxially growing the semiconductor material in S/D openings 710 to remove residuals or contaminants left when forming S/D openings 710.

In some embodiments, epitaxially growing the semiconductor material in S/D openings 710 can include epitaxially growing the semiconductor material having a same crystallographic orientation as substrate 104 and/or fin structures 106. In some embodiments, epitaxially growing the semiconductor material in S/D openings 710 can include epitaxially growing the semiconductor material along a [100] or [110] crystallographic orientation. In some embodiments, epitaxially growing the semiconductor material in S/D openings 710 can include a deposition process, such as a PECVD process at a temperature of about 500° C. or below (e.g., at a temperature of about 500° C. to about 20° C., at a temperature of about 400° C. or below, or at a temperature of about 400° C. to about 20° C.).

In some embodiments, epitaxially growing the semiconductor material can include epitaxially growing the semiconductor material in a crystalline form. In some embodiments, unwanted amorphous form of the semiconductor material can be deposited in S/D openings 710 along with the crystalline form of the semiconductor material. Thus, the process of epitaxially growing the semiconductor material in S/D openings 710 can also include an etching process to selectively etch the unwanted amorphous form of the semiconductor material along with the deposition process to grow the crystalline form of the semiconductor material, as discussed below. In some embodiments, the deposition process and the etching process can be performed in-situ in a PECVD chamber. In some embodiments, the unwanted amorphous form of the semiconductor material can be amorphous silicon (a-Si) and the crystalline form can be crystalline silicon (c-Si). In some embodiments, the etch selectivity between the amorphous form (e.g., a-Si) and crystalline form (e.g., c-Si) of the semiconductor material during the etching process can be greater than about 6. The term “etch selectivity” is used herein to define a ratio of an etching rate of a-Si to an etching rate of c-Si,

In some embodiments, epitaxially growing the semiconductor material in S/D openings 710 can include (i) maintaining a base pressure in the PECVD chamber of about 10⁻⁷ torr to about 1520 torr, (ii) maintaining a processing pressure in the PECVD chamber of about 104 torr to about 1520 torr, (iii) generating a plasma in the PECVD chamber, (iv) controlling a plasma condition to be in an ‘on’ condition (also referred to as a “plasma generated condition”) or in an ‘off’ condition (also referred to as a “plasma terminated condition”) during the deposition process and the etching process, as described in detail below, (v) using a frequency of the plasma to be about 1 Hz to about 3 GHz, (vi) using a power of the plasma to be about 1 W to about 10000 W, and/or (vii) using a frequency of a source pulsing of the plasma to be about 1 Hz to about 1 MHz. The plasma ‘on’ condition refers to a state of plasma generation and the plasma ‘off’ condition refers to a state of plasma termination.

In some embodiments, epitaxially growing the semiconductor material in S/D openings 710 can include epitaxially growing an undoped semiconductor material in the PECVD process. In some embodiments, epitaxially growing the undoped semiconductor material can include epitaxially growing Si, Ge, Sn, SiC, SiGe, SiSn, silicon germanium carbon (SiGeC), silicon germanium tin (SiGeSn), or germanium tin (GeSn). In some embodiments, epitaxially growing the undoped semiconductor material can include flowing processing gases, including a carrier gas, a precursor gas, and an etching gas, in the PECVD chamber during the deposition process and/or the etching process, as described in detail below. In some embodiments, the carrier gas can include hydrogen (H₂), helium (He), argon (Ar), nitrogen (N₂), or a combination thereof. In some embodiments, a flow rate of the carrier gas can be about 1 sccm to about 50000 sccm. In some embodiments, the precursor gas can be or include a Si precursor gas, a Ge precursor gas, a Sn precursor gas, or a combination thereof. In some embodiments, the Si precursor gas can include silanes (SiₘH₂ₘ₊₂₋ₙXₙ, with 1≤m≤5 and 0≤n≤(2m+2)), cyclosilanes (SiₘH₂ₘ₋ₙXₙ, with 3≤m≤5 and 0≤n≤2m), or a combination thereof. In some embodiments, the Ge precursor gas can include germanes (GeₘH₂ₘ₊₂₋ₙXₙ, with 1≤m≤5 and 0≤n≤(2m+2)), cyclogermanes (SiₘH₂ₘ₋ₙXₙ, with 3≤m≤5 and 0≤n≤2m), or a combination thereof. In some embodiments, the Sn precursor gas can include stannous precursors (SnH₂₋ₙXₙ, with 0≤n≤2), stannic precursors (SnH₄₋ₙXₙ, with 0≤n≤4), or a combination thereof. In the above examples of precursor gas, X can be fluorine (F), chlorine (Cl), bromine (Br), iodine (I), or methyl (CH₃). In some embodiments, a flow rate of the precursor gas can be about 0.01 sccm to about 5000 sccm. In some embodiments, the etching gas can include H₂, fluorine (F₂), chlorine (Cl₂), hydrogen fluoride (HF), hydrogen chloride (HCl), hydrogen bromide (HBr), or a combination thereof. In some embodiments, a flow rate of the etching gas can be about 0.1 sccm to about 5000 sccm.

In some embodiments, epitaxially growing the semiconductor material in S/D openings 710 can include epitaxially growing a p-type semiconductor material using the PECVD process. In some embodiments, epitaxially growing the p-type semiconductor material can include epitaxially growing Si, SiB, silicon aluminum (SiAl), silicon gallium (SiGa), silicon indium (SiIn), Ge, germanium boron (GeB), germanium aluminum (GeAl), germanium gallium (GeGa), germanium indium (GeIn), Sn, tin boron (SnB), tin aluminum (SnAl), tin gallium (SnGa), tin indium (SnIn), SiC, silicon carbon boron (SiCB), silicon carbon aluminum (SiCAl), silicon carbon gallium (SiCGa), silicon carbon indium (SiCIn), SiGe, silicon germanium boron (SiGeB), silicon germanium aluminum (SiGeAl), silicon germanium gallium (SiGeGa), silicon germanium indium (SiGeIn), SiSn, silicon tin boron (SiSnB), silicon tin aluminum (SiSnAl), silicon tin gallium (SiSnGa), silicon tin (SiSnIn), silicon germanium carbon (SiGeC), silicon germanium carbon boron (SiGeCB), silicon germanium carbon (SiGeCAl), silicon germanium carbon gallium (SiGeCGa), silicon germanium carbon indium (SiGeCIn), silicon germanium tin (SiGeSn), silicon germanium tin boron (SiGeSnB), silicon germanium tin aluminum (SiGeSnAl), silicon germanium tin gallium (SiGeSnGa), silicon germanium tin indium (SiGeSnIn), germanium tin (GeSn), germanium tin boron (GeSnB), germanium tin aluminum (GeSnAl), germanium tin gallium (GeSnGa), germanium tin indium (GeSnIn), or a combination thereof.

In some embodiments, epitaxially growing the p-type semiconductor material can include flowing processing gases, including the carrier gas, the precursor gas, the etching gas, and a p-type dopant precursor gas, in the PECVD chamber during the deposition process and/or the etching process, as described in detail below. The discussion of the carrier gas, the precursor gas, and the etching gas in epitaxially growing the undoped semiconductor material applies in epitaxially growing the p-type semiconductor material, unless mentioned otherwise. In some embodiments, the p-type dopant precursor gas can be or include a boron (B) precursor gas, an aluminum (Al) precursor gas, a gallium (Ga) precursor gas, an indium (In) precursor gas, or a combination thereof. In some embodiments, the B precursor gas can include boranes (BH₃, B₂H₄, B₂H₆, B₃H₅, B₃H₇, BₘHₘ₊₄, and/or BₘHₘ₊₆, with m>3), boron halides (BX₃ and/or B₂X₄), alkyl boranes ((CₘH₂ₘ₊₁)₃B, with m≥1), or a combination thereof. In some embodiments, the Al precursor gas can include alanes (AlH₃ and/or Al₂H₄), haloalanes (AlX₃), alkylalanes ((CₘH₂ₘ₊₁)ₙAlX₃₋ₙ, with m≥1, 0≤n≤3), or a combination thereof. In some embodiments, the Ga precursor gas can include gallanes (GaH₃ and/or Ga₂H₄), gallium halides (GaX₃), alkylgallanes ((CₘH₂ₘ₊₁)ₙGaX₃₋ₙ, with m≥1, 0≤n≤3), or a combination thereof. In some embodiments, the In precursor gas can include indium halides (GaX₃), alkylindiums ((CₘH₂ₘ₊₁)ₙInX₃₋ₙ, with m≥1, 0≤n≤3), or a combination thereof. In the above examples of p-type dopant precursor gas, X can represent Cl, Br, or I. In some embodiments, a flow rate of the p-type dopant precursor gas can be about 0.001 sccm to about 5000 sccm.

In some embodiments, epitaxially growing the semiconductor material in S/D openings 710 can include epitaxially growing an n-type semiconductor material using the PECVD process. In some embodiments, epitaxially growing the n-type semiconductor material can include epitaxially growing Si, SiP, silicon arsenic (SiAs), silicon antimony (SiSb), silicon bismuth (SiBi), Ge, germanium phosphide (GeP), germanium arsenic (GeAs), germanium antimony (GeSb), germanium bismuth (GeBi), Sn, tin phosphide (SnP), tin arsenic (SnAs), tin antimony (SnSb), tin bismuth (SnBi), silicon carbon (SiC), silicon carbon phosphide (SiCP), silicon carbon arsenic (SiCAs), silicon carbon antimony (SiCSb), silicon carbon bismuth (SiCBi), silicon germanium (SiGe), silicon germanium phosphide (SiGeP), silicon germanium arsenic (SiGeAs), silicon germanium antimony (SiGeSb), silicon germanium bismuth (SiGeBi), silicon tin (SiSn), silicon tin phosphide (SiSnP), silicon tin arsenic (SiSnAs), silicon tin antimony (SiSnSb), silicon tin bismuth (SiSnBi), silicon germanium carbon (SiGeC), silicon germanium carbon phosphide (SiGeCP), silicon germanium carbon arsenic (SiGeCAs), silicon germanium carbon antimony (SiGeCSb), silicon germanium carbon bismuth (SiGeCBi), silicon germanium tin (SiGeSn), silicon germanium tin phosphide (SiGeSnP), silicon germanium tin arsenic (SiGeSnAs), silicon germanium tin antimony (SiGeSnSb), silicon germanium tin bismuth (SiGeSnBi), germanium tin (GeSn), germanium tin phosphide (GeSnP), germanium tin arsenic (GeSnAs), germanium tin antimony (GeSnSb), germanium tin bismuth (GeSnBi), or a combination thereof.

In some embodiments, epitaxially growing the n-type semiconductor material can include flowing processing gases, including the carrier gas, the precursor gas, the etching gas, and an n-type dopant precursor gas, in the PECVD chamber during the deposition process and/or the etching process, as described in detail below. The discussion of the carrier gas, the precursor gas, and the etching gas in epitaxially growing the undoped semiconductor material applies in epitaxially growing the n-type semiconductor material, unless mentioned otherwise. In some embodiments, the n-type dopant precursor gas can be or include a phosphorous (P) precursor gas, an arsenic (As) precursor gas, an antimony (Sb) precursor gas, a bismuth (Bi) precursor gas, or a combination thereof. In some embodiments, the P precursor gas can include phosphanes (PH₃ and/or PₘHₘ₊₂, with m>1), phosphorus halides (PX₃, PX₅, and/or P₂X₄), or a combination thereof. In some embodiments, the As precursor gas can include arsanes (AsH₃ and/or AsₘHₘ₊₂, with m>1) and arsenic halides (AsX₃ and/or AsX₅), or a combination thereof. In some embodiments, the Sb precursor gas can include stibane (SbH₃), antimony halides (SbX₃ and/or SbX₅), or a combination thereof. In some embodiments, the Bi precursor gas can include bismuthane (BiH₃), bismuth halides (BiX₃ and/or BiX₅), or a combination thereof. In the above examples of n-type dopant precursor gas, X can represent Cl, Br, or I. In some embodiments, a flowrate of the n-type dopant precursor gas can be about 0.001 sccm to about 5000 sccm.

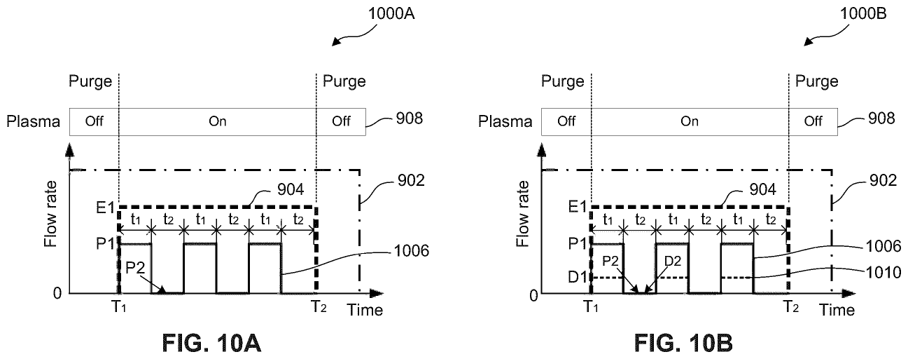

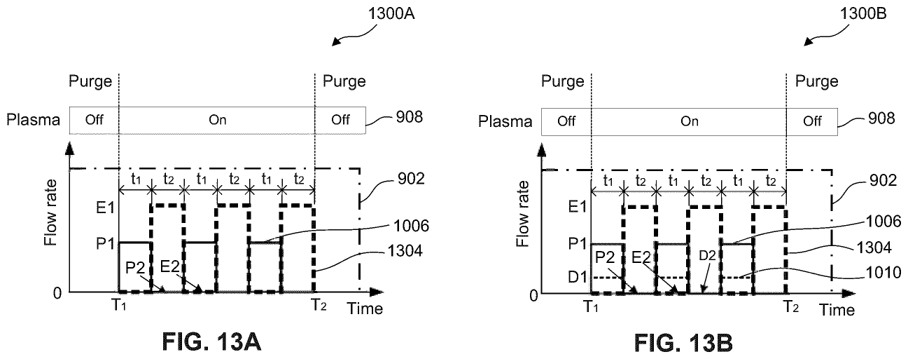

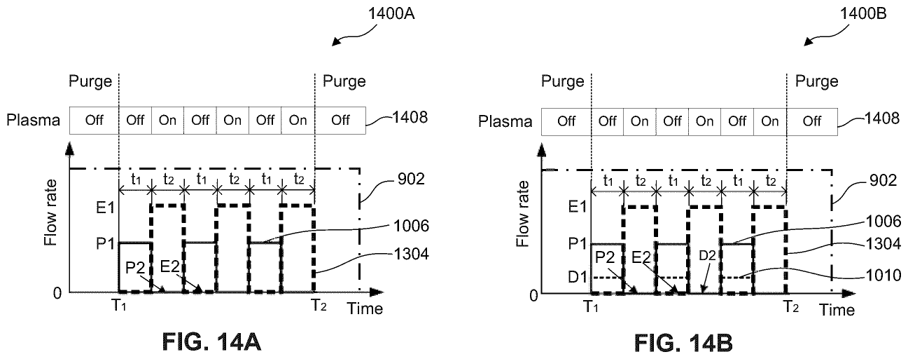

In some embodiments, the epitaxial growth of undoped semiconductor material in S/D openings 710, as shown in FIGS. 8A and 8B, can be performed using process 900A of FIG. 9A, process 1000A of FIG. 10A, process 1300A of FIG. 13A, or process 1400A of FIG. 14A, as described in detail below. In some embodiments, the epitaxial growth of doped semiconductor material in S/D openings 710, as shown in FIGS. 8A and 8B, can be performed using process 900B of FIG. 9B, process 1000B of FIG. 10B, process 1300B of FIG. 13B, or process 1400B of FIG. 14B, as described in detail below. In some embodiments, each of process 1000A, 1000B, 1300A, 1300B, 1400A, and 1400B can be performed in-situ in the PECVD chamber.

Referring to FIG. 9A, in some embodiments, epitaxially growing the undoped semiconductor material can include controlling the plasma condition and the flow rates of the carrier gas, the precursor gas, and the etching gas during the deposition process and the etching process. For example, as described by process 900A with reference to FIG. 9A, the process of epitaxially growing the undoped semiconductor material in S/D openings 710 can start at time T₁ and end at time T₂. A plasma can be provided between time T₁ and time T₂, as shown by a plasma condition 908 being ‘on’ between time T₁ and time T₂ and ‘off’ otherwise. A carrier gas flow rate 902 can be maintained at a non-zero value, starting before time T₁ and ending after time T₂. An etching gas flow rate 904 and a precursor gas flow rate 906 can both be maintained at a non-zero value E1 and P1, respectively, starting at time T₁ and ending at time T₂. In other words, the etching gas and the precursor gas can co-flow between time T₁ and time T₂. In some embodiments, a ratio between precursor gas flow rate 906 and etching gas flow rate 904 (i.e., P1:E1) can be about 50000:1 to about 1:50000 to adequately grow a high quality crystalline semiconductor material in S/D openings 710. In some embodiments, gas purging processes can be performed before time T₁ and after time T₂, as shown in FIG. 9A.

In some embodiments, the precursor gas can epitaxially grow the undoped semiconductor material in the crystalline form on fin structures 106. In some embodiments, the precursor gas can also deposit the undoped semiconductor material in the amorphous form on dielectric surfaces, such as surfaces of thermal oxide layer 322, gate spacers 514, and STI regions 116. The etching gas can selectively etch the amorphous form of the undoped semiconductor material. In some embodiments, the etch selectivity can be greater than about 6 at a temperature of about 500° C. or below (e.g., at a temperature of about 500° C. to about 20° C., at a temperature of about 400° C. or below, or at a temperature of about 400° C. to about 20° C.). In some embodiments, co-flowing the precursor gas and the etching gas with etch selectivity greater than about 6 can epitaxially grow S/D regions 110 with undoped semiconductor material and prevent the formation of nodule and clog on sidewalls of S/D openings 710 having a CD of about 5 nm to about 30 nm, and an AR greater than about 5.

Referring to FIG. 9B, in some embodiments, epitaxially growing the p-type or n-type semiconductor material can include controlling the plasma condition and the flow rates of the carrier gas, the precursor gas, the etching gas, and the dopant precursor gas during the deposition process and the etching process. The discussion of process 900A in FIG. 9A applies to process 900B of FIG. 9B, unless mentioned otherwise. As described by process 900B with reference to FIG. 9B, a dopant precursor gas flow rate 910 can be maintained at a non-zero value D1 starting at time T₁ and ending at time T₂, together with the etching gas flow rate 904 and the precursor gas flow rate 906. In other words, the etching gas, the precursor gas, and the dopant precursor gas can co-flow between time T₁ and time T₂. In some embodiments, a ratio between dopant precursor gas flow rate 910 and precursor gas flow rate 906 (i.e., D1:P1) can be about 1:1000 to about 1000:1 to adequately grow a high quality crystalline doped semiconductor material in S/D openings 710. In some embodiments, gas purging processes can be performed before time T₁ and after time T₂, as shown in FIG. 9B.

In some embodiments, the precursor gas and the dopant precursor gas can epitaxially grow the p-type or n-type semiconductor material in a crystalline form on fin structures 106. In some embodiments, the precursor gas and the dopant precursor gas can also deposit the p-type or n-type semiconductor material in an amorphous form on dielectric surfaces, such as surfaces of thermal oxide layer 322, gate spacers 514, and STI regions 116. The etching gas can selectively etch the amorphous form of the p-type or n-type semiconductor material. In some embodiments, the etch selectivity can be greater than about 6 at a temperature of about 500° C. or below (e.g., at a temperature of about 500° C. to about 20° C., at a temperature of about 400° C. or below, or at a temperature of about 400° C. to about 20° C.). In some embodiments, co-flowing the precursor gas, the dopant precursor gas, and the etching gas with etch selectivity greater than about 6 can epitaxially grow S/D regions 110 with p-type or n-type semiconductor material and prevent the formation of nodule and clog on sidewalls of openings 710 having a CD of about 5 nm to about 30 nm, and an AR greater than about 5.

Referring to FIG. 10A, in some embodiments, epitaxially growing the undoped semiconductor material can include controlling the flow rate of the precursor gas during the deposition process and the etching process in a cyclic manner, such as by process 1000A of FIG. 10A. The discussion of process 900A in FIG. 9A applies to process 1000A of FIG. 10A, unless mentioned otherwise. During the process of epitaxially growing the undoped semiconductor material between time T₁ and time T₂, a precursor gas flow rate 1006 can be varied in gas flow cycles, instead of being maintained at a value P1 between time T₁ and time T₂, as shown in FIGS. 9A and 9B. Each gas flow cycle can include first and second phases and can have a time duration of t₁+t₂. In the first phase having a time duration t₁, precursor gas flow rate 1006 can be maintained at value P1, which can be a non-zero value. In the second phase having a time duration t₂, precursor gas flow rate 1006 can be maintained at a value P2 different from value P1. In some embodiments, value P2 can be lower than value P1. For example, as shown in FIG. 10A, value P2 can be zero.

In some embodiments, varying precursor gas flow rate 1006 in gas flow cycles can facilitate the etching gas to adequately remove greater amount of the amorphous form of the undoped semiconductor material during the second phase of the gas flow cycle when precursor gas flow rate 1006 is at a lower value compared to that during the first phase of the gas flow cycle. In some embodiments, varying precursor gas flow rate 1006 in gas flow cycles of process 1000A can epitaxially grow the undoped semiconductor material selectively on fin structures 106 with higher etch selectivity and/or less amorphous form at a temperature of about 500° C. or below compared to processes 900A and 900B. In some embodiments, the deposition rate (also referred to as “epitaxial growth rate”) during the first phase of each gas flow cycle of process 1000A can be higher than that during the second phase of each gas flow cycle of process 1000A. In some embodiments, the deposition rate can be higher than that of the etching rate during the first phase of each gas flow cycle and the etching rate can be higher than that of the deposition rate during the second phase of each gas flow cycle. In some embodiments, gas purging processes can be performed before time T₁ and after time T₂, and not performed between the gas flow cycles of the precursor gas, as shown in FIG. 10A.

Referring to FIG. 10B, in some embodiments, epitaxially growing the p-type or n-type semiconductor material can include controlling the flow rates of the precursor gas and the dopant precursor gas during the deposition process and the etching process in a cyclic manner, such as by process 1000B of FIG. 10B. The discussion of process 1000A in FIG. 10A applies to process 1000B of FIG. 10B, unless mentioned otherwise. During the process of epitaxially growing the p-type or n-type semiconductor material between time T₁ and time T₂, a dopant precursor gas flow rate 1010 can be varied in gas flow cycles along with precursor gas flow rate 1006, instead of being maintained at a constant value D1 between time T₁ and time T₂, as shown in FIG. 9B. In the first phase of each gas flow cycle, dopant precursor gas flow rate 1010 can be maintained at value D1, which can be a non-zero value. In the second phase of each gas flow cycle, dopant gas flow rate 1010 can be maintained at a value D2 different from value D1. In some embodiments, value D2 can be lower than value D1. For example, as shown in FIG. 10B, value D2 can be zero. Thus, during the first phase of each gas flow cycle of process 1000B, dopant precursor gas can co-flow with the precursor gas. In some embodiments, varying precursor gas flow rate 1006 and dopant precursor gas flow rate 1010 in gas flow cycles can adequately facilitate epitaxially growing the p-type or n-type semiconductor material selectively on fin structures 106.

Referring to FIG. 13A, in some embodiments, epitaxially growing the undoped semiconductor material can include controlling the flow rate of the etching gas and the precursor gas during the deposition process and the etching process in a cyclic manner, such as by process 1300A of FIG. 13A. The discussion of process 1000A of FIG. 10A applies to process 1300A of FIG. 13A, unless mentioned otherwise. During the process of epitaxially growing the undoped semiconductor material between time T₁ and time T₂, an etching gas flow rate 1304 can be varied in gas flow cycles, instead of being maintained at a constant value E1 as shown in FIGS. 9A-9B and 10A-10B. In the first phase of each gas flow cycle, etching gas flow rate 1304 can be maintained at a value E2. In the second phase of each gas flow cycle, etching gas flow rate 1304 can be maintained at value E1 different from value E2. In some embodiments, value E1 can be greater than value E2. For example, as shown in FIG. 13A, value E2 of etching gas flow rate 1304 can be zero in the first phase, while value E1 can be non-zero in the second phase. Thus, in some embodiments, in the first phase of each gas flow cycle of process 1300A, precursor gas flow rate 1006 can be non-zero, while etching gas flow rate 1304 can be zero, as shown in FIG. 13A. And, in the second phase of each gas flow cycle of process 1300A, etching gas flow rate 1304 can be non-zero, while value precursor gas flow rate 1006 can be zero, as shown in FIG. 13A. In other words, the precursor gas and the etching gas may not be supplied to the PECVD chamber at the same time and may not co-flow in the PECVD chamber during each gas flow cycle of process 1300A. The precursor gas and the etching gas can be alternatively supplied to the PECVD chamber and alternatively flow in the PECVD chamber between time T₁ and time T₂. Thus, in process 1300A, the deposition process can be performed during the first phase of each gas flow cycle and not during the second phase of each gas flow cycle. On the other hand, in process 1300A, the etching process can be performed during the second phase of each gas flow cycle and not during the first phase of each gas flow cycle

In some embodiments, alternatively flowing the precursor gas and the etching gas during each gas flow cycle of process 1300A can facilitate faster growth of the undoped semiconductor material during the first phase of the gas flow cycle compared to processes 900A, 900B, 1000A, and 1000B. Also, alternatively flowing the precursor gas and the etching gas during each gas flow cycle of process 1300A can epitaxially grow the undoped semiconductor material on fin structures 106 with higher etch selectivity at a temperature of about 500° C. or below compared to processes 900A, 900B, 1000A, and 1000B.

Referring to FIG. 13B, in some embodiments, epitaxially growing the p-type or n-type semiconductor material can include controlling the flow rates of the etching gas, the precursor gas, and the dopant precursor gas during the deposition process and the etching process in a cyclic manner, such as by process 1300B of FIG. 13B. The discussion of process 1000B of FIG. 10B and process 1300A of FIG. 13A applies to process 1300B of FIG. 13B, unless mentioned otherwise. During the process of epitaxially growing the p-type or n-type semiconductor material between time T₁ and time T₂, as shown in FIG. 13B, (i) during the first phase of each gas flow cycle, value E2 of etching gas flow rate 1304 can be maintained at zero, while values P1 and D1 of precursor gas flow rate 1006 and dopant precursor gas flow rate 1010 can be maintained at a non-zero value, and (ii) during the second phase of each gas flow cycle, value E1 of etching gas flow rate 1304 can be maintained at a non-zero value, while values P2 and D2 of precursor gas flow rate 1006 and dopant precursor gas flow rate 1010 can be maintained at zero.

Referring to FIG. 14A, in some embodiments, epitaxially growing the undoped semiconductor material can include controlling the plasma condition, the etching gas, and the precursor gas during the deposition process and the etching process in a cyclic manner, such as by process 1400A of FIG. 14A. The discussion of process 1300A of FIG. 13A applies to process 1400A of FIG. 14A, unless mentioned otherwise. In some embodiments, during the process of epitaxially growing the undoped semiconductor material between time T₁ and time T₂, a plasma condition 1408 can be varied in gas flow cycles along with etching gas flow rate 1304 and precursor gas flow rate 1006. In some embodiments, plasma condition 1408 can be ‘off’ during the first phase of each gas flow cycle of process 1400A and can be ‘on’ during the second phase of each gas flow cycle of process 1400A, as shown in FIG. 14A. Thus, the plasma can be generated (i.e., ‘on’ condition) in the PECVD chamber when etching gas flow rate 1304 is maintained at value E1 and precursor gas flow rate 1006 is maintained at value P2. The plasma can be absent (i.e., ‘off’ condition) in the PECVD chamber when etching gas flow rate 1304 is maintained at value E2 and precursor gas flow rate 1006 is maintained at value P1. In some embodiments, generating plasma during the etching process in the second phases of process 1400A can provide higher etch selectivity at a temperature of about 500° C. or below compared to processes 900A, 900B, 1000A, 1000B, 1300A, and 1300B.

Referring to FIG. 14B, in some embodiments, epitaxially growing the p-type or n-type semiconductor material can include controlling the plasma condition, the etching gas, the precursor gas, and the dopant precursor gas during the deposition process and the etching process in a cyclic manner, such as by process 1400B of FIG. 14B. The discussion of process 1300B FIG. 13B and process 1400A of FIG. 14A applies to process 1400B of FIG. 14B, unless mentioned otherwise. In some embodiments, during the process of epitaxially growing the p-type or n-type semiconductor material between time T₁ and time T₂, plasma condition 1408, etching gas flow rate 1304, and precursor gas flow rate 1006 can be varied as discussed with reference to FIG. 14A, and dopant precursor gas flow rate 1010 can be varied as discussed with reference to FIG. 13B.

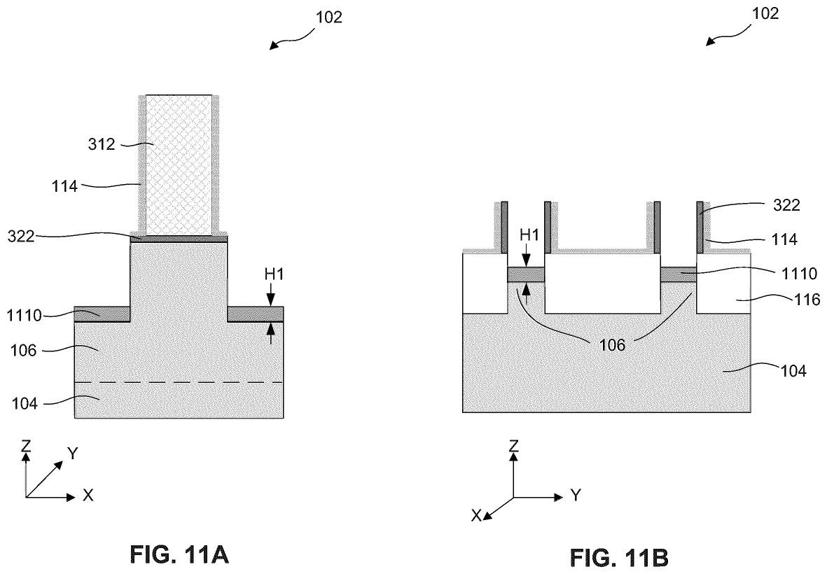

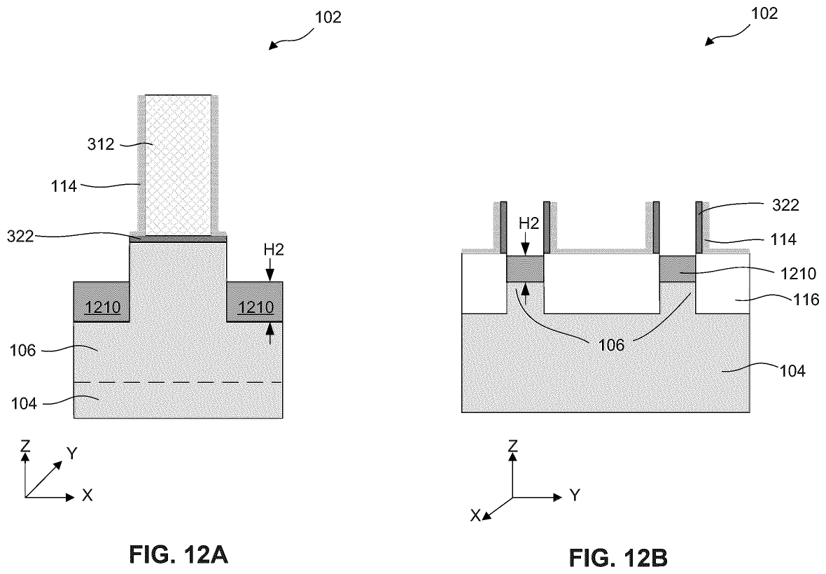

Referring to FIGS. 8A, 8B, 10A-14A and 10B-14B, the following discussion of the epitaxial growth of the semiconductor material in S/D openings 710 during gas flow cycles applies to each of process 1000A, 1000B, 1300A, 1300B, 1400A, and 1400B, unless mentioned otherwise. The process of epitaxially growing the semiconductor material between time T₁ and time T₂ can include one or more gas flow cycles. In some embodiments, after the first gas flow cycle is completed, S/D regions 1110 with height H1 can be formed in S/D openings 710, as shown in FIGS. 11A and 11B. In some embodiments, after the second gas flow cycle is completed, S/D regions 1210 with height H2 greater than H1 can be formed in S/D openings 710, as shown in FIGS. 12A and 12B. In some embodiments, after the multiple gas flow cycles are completed at time T₂, S/D regions 810 can be formed, as shown in FIGS. 8A and 8B. Though three gas flow cycles are shown in each of FIGS. 10A, 10B, 13A, 13B, 14A, and 14B, processes 1000A, 1000B, 1300A, 1300B, 1400A, and 1400B of respective FIGS. 10A, 10B, 13A, 13B, 14A, and 14B can have any number of gas flow cycles.

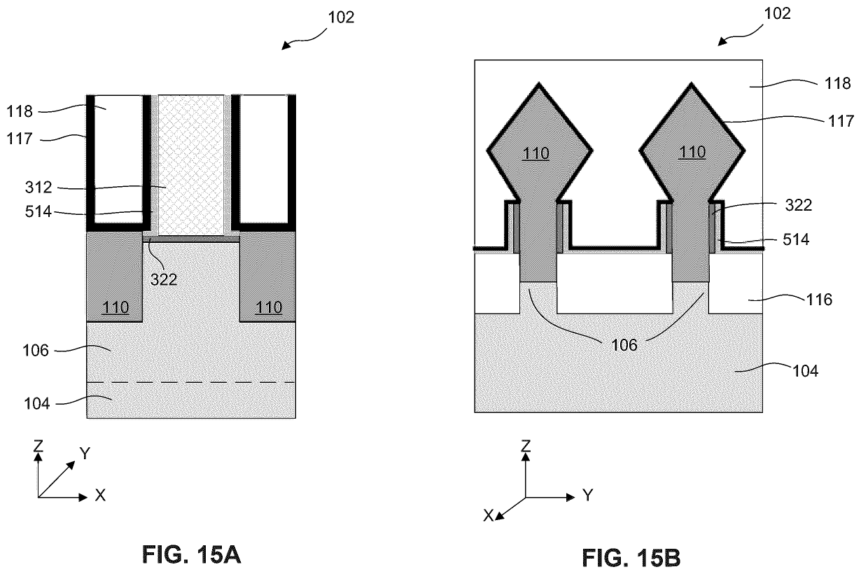

After the formation of S/D regions 110, ESL 117 and ILD layer 118 can be formed on S/D regions 110, as shown in FIGS. 15A and 15B. In some embodiments, after the formation of S/D regions 110, an annealing process can be performed to densify gate spacer 514. For example, gate spacer 514 can be annealed at an annealing temperature. In some embodiments, the annealing temperature can be about 200° C. to about 1300° C. (e.g., about 1200° C. to about 1250° C.). The annealing process can remove contaminants in gate spacer 514 and improve atomic alignment of atoms in gate spacer 514 to remove crystallographic defects, such as vacancies and dislocations. The annealing process can improve a quality of gate spacer 514 as an isolation structure between polysilicon structure 312 and S/D regions 110.

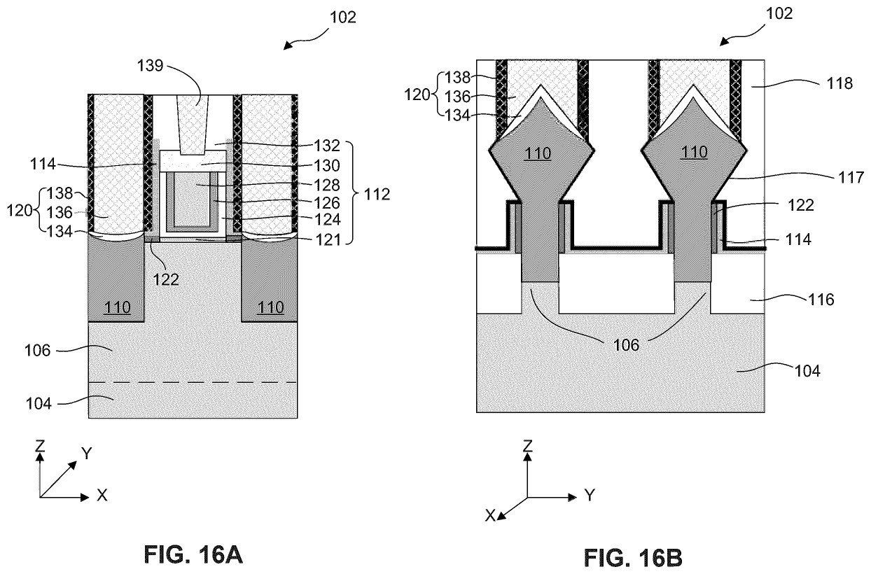

Referring to FIG. 2, in operation 225, the polysilicon structure can be replaced by a gate structure. For example, as described with reference to FIGS. 16A and 16B, polysilicon structure 312 is replaced by gate structure 112. Replacing the polysilicon structure 312 with gate structure 112 can include sequential operations of (i) removing polysilicon structure 312, (ii) removing an exposed portion of thermal oxide layer 322 to expose a portion of fin structures 106, (iii) forming interfacial oxide layer 121 on the exposed portion of fin structures 106, (vi) depositing gate oxide layer 124 on interfacial oxide layer 121 and sidewalls of gate spacers 514, (v) depositing WFM layer 126 on gate oxide layer 124, (vi) depositing gate metal fill layer 128 on WFM layer 126, (ix) etching gate spacers 514 to form gate spacers 114, (x) forming conductive capping layer 130 between gate spacers 114 and on gate oxide layer 124, WFM layer 126, and gate metal fill layer 128, and (xi) forming insulating capping layer 132 on conductive capping layer 130, as shown in FIGS. 16A and 16B.

Referring to FIG. 2, in operation 230, contact structures can be formed on the S/D regions and on the gate structure. For example, as described with reference to FIGS. 16A and 16B, S/D contact structures 120 are formed on S/D regions 110, and gate contact structure 139 is formed on gate structure 112. In some embodiments, forming S/D contact structures 120 can include sequential operations of i) removing portions of ESL 117 and ILD layer 118 to expose S/D regions 110, ii) forming silicide layers 134 on S/D regions 110, iii) forming contact plugs 136 on silicide layers 134, and iv) forming nitride barrier layers 138 along sidewalls of contact plugs 136. In some embodiments, forming gate contact structures 139 can include forming an opening through insulating capping layer 132 and into conductive capping layer 130, and ii) filling the opening with a conductive material to form gate contact structure 139.

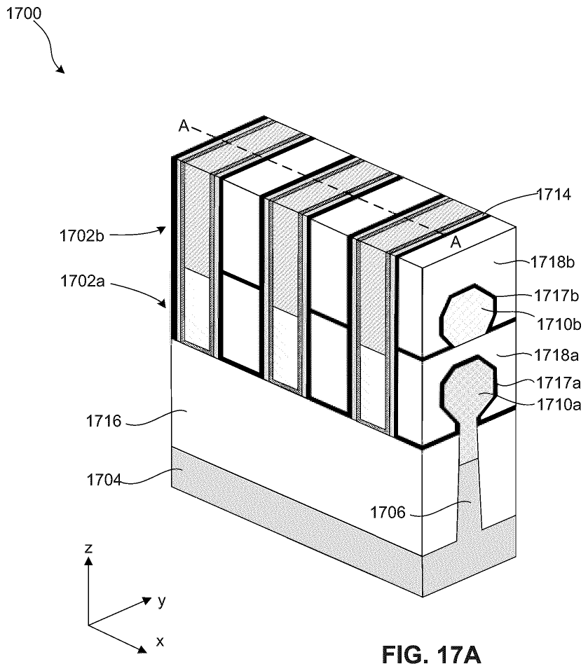

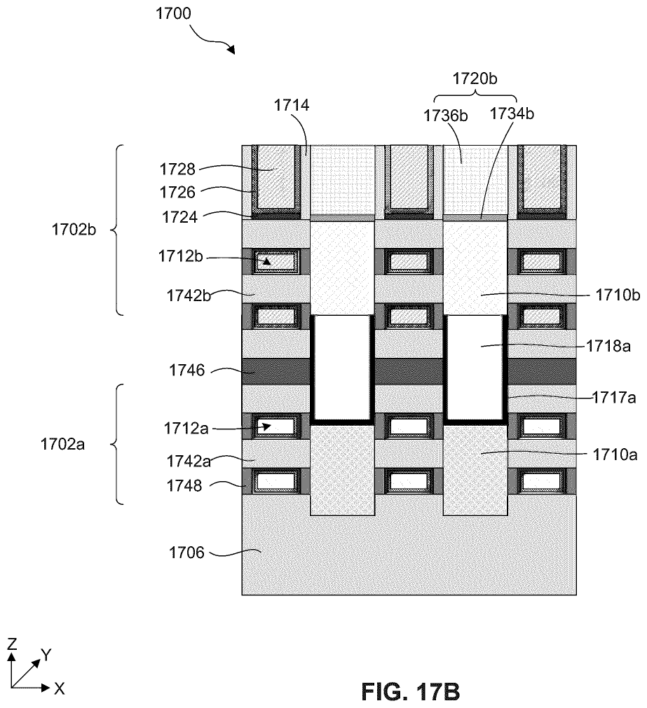

FIG. 17A illustrates an isometric view of a CFET 1700, according to some embodiments. FIG. 17B illustrates a cross-sectional view of CFET 1700 along line A-A, according to some embodiments. FIG. 17B illustrates a view of CFET 1700 with additional structures that are not shown in FIG. 17A for simplicity. The discussion of elements with the same annotations applies to each other, unless mentioned otherwise.

Referring to FIGS. 17A and 17B, CFET 1700 can include (i) a substrate 1704, (ii) a fin base 1706 disposed on substrate 1704, and (iii) STI regions 1716 disposed on substrate 1704 and adjacent to fin base 1706. In some embodiments, substrate 1704 can be a semiconductor material, such as Si, Ge, SiGe, a silicon-on-insulator (SOI) structure, and a combination thereof. Further, substrate 1704 can be doped with p-type dopants (e.g., boron, indium, aluminum, or gallium) or n-type dopants (e.g., phosphorus arsenic, antimony, or bismuth). In some embodiments, a top surface of substrate 1704 can be normal to [100] or [110] crystallographic orientation. In some embodiments, fin base 1706 can include a material similar to substrate 1704 and can have elongated sides extending along an X-axis. In some embodiments, STI regions 1716 can include an insulating material, such as silicon oxide, SiN, SiCN, SiOCN, and silicon germanium oxide.

In some embodiments, CFET 1700 can further include (i) a GAA FET 1702a disposed on fin base 1706 and STI regions 1716, (ii) a GAA FET 1702b disposed on GAA FET 1702a, and (iv) channel isolation layer 1746 disposed between GAA FETs 1702a and 1702b. GAA FET 1702a can have a conductivity type (e.g., n-type or p-type) different from that of GAA FET 1702b. In some embodiments, GAA FET 1702a can be n-type and GAA FET 1702b can be p-type or vice versa.

Referring to FIGS. 17A and 17B, in some embodiments, GAA FET 1702a can include (i) stacks of nanostructured layers 1742a disposed on fin base 1706, (ii) gate structures 1712a surrounding nanostructured layers 1742a, (iii) SD regions 1710a disposed adjacent to nanostructured layers 1742a, (iv) ESLs 1717a disposed on S/D regions 1710a, (v) ILD layers 1718a disposed on ESLs 1717a, and (vi) inner spacers 1748 disposed adjacent to gate structures 1712a. Nanostructured layers 1742 that are adjacent to and in direct contact with S/D regions 1710a can function as channel regions. Nanostructured layer 1742a that is disposed directly on bottom surfaces of channel isolation layer 1746 and is not in contact with S/D regions 1710a, as shown in FIG. 17B, do not function as channel regions. Though a single row of channel region is shown in FIG. 17B, GAA FET 1702a can have one or more rows of channel regions.

In some embodiments, GAA FET 1702b can include (i) stacks of nanostructured layers 1742b disposed on channel isolation layer 1746, (ii) gate structures 1712b surrounding nanostructured layers 1742b, (iii) S/D regions 1710b disposed adjacent to nanostructured layers 1742b, (iv) S/D contact structures 1720b disposed on front-sides of S/D regions 1710b, (v) ESLs 1717b disposed on S/D regions 1710b, (vi) ILD layers 1718b disposed on ESLs 1717b, (vii) gate spacers 1714 disposed adjacent to gate structures 1712b, and (viii) inner spacers 1748 disposed adjacent to gate structures 1712b. Nanostructured layers 1742b that are adjacent to and in direct contact with S/D regions 1710b can function as channel regions. Nanostructured layer 1742b that is disposed directly on top surfaces of channel isolation layer 1746, as shown in FIG. 17B, do not function as channel regions. Though two rows of channel regions are shown in FIG. 17B, GAA FET 1702b can have one or more rows channel regions.

In some embodiments, the gate structures of CFET 1700 can have substantially equal gate lengths along an X-axis. Gate structures 1712a can be referred to as “bottom gate structures” and gate structures 1712b can be referred to as “top gate structures.”

As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. In some embodiments, nanostructured layers 1742a and 1742b can have be in the form of nanosheets, nanowires, nanorods, nanotubes, or other suitable nanostructured shapes.

In some embodiments, ESLs 1717a and 1717b, ILD layers 1718a and 1718b, inner spacers 1748, and gate spacers 1714 can include an insulating material, such as silicon oxide, silicon nitride (SiN), silicon carbon nitride (SiCN), silicon oxycarbon nitride (SiOCN), and silicon germanium oxide.

Channel isolation layer 1746 can electrically isolate channel regions of GAA FET 1702a from the overlying channel regions of GAA FET 1702b. In some embodiments, channel isolation layer 1746 can include a dielectric material with a dielectric constant ranging from about 3 to about 25. In some embodiments, the dielectric material can include SiO₂, SiN, silicon oxynitride (SiOₓN_{y}), silicon oxycarbon nitride (SiOₓC_{y}N_{z}), HfO₂, ZrO₂, or a combination thereof. In some embodiments, the dielectric material can include a material with a dielectric constant lower than the dielectric constant of SiO₂ (about 3.9), such as hydrogenated carbon-doped silicon oxide (SiCOH) (dielectric constant ranging from about 2.7 to about 3.3), fluorosilicate glass (FSG) (dielectric constant about 3.5 to about 3.9), nanopore carbon doped oxide (CDO), black diamond (BD), a benzocyclobutene (BCB) based polymer, an aromatic (hydrocarbon) thermosetting polymer (ATP), hydrogen silsesquioxane (HSQ), methyl silsesquioxane (MSQ), poly-arylene ethers (PAE), diamond-like carbon (DLC) doped with nitrogen, and combinations thereof. In some embodiments, a thickness of channel isolation layer 1746 can range from about 10 nm to about 30 nm for adequate electrical isolation between channel regions of GAA FETs 1702a and 1702b without compromising device size and manufacturing cost. In some embodiments, channel isolation layer 1746 can have side surfaces with linear side profiles, faceted side profiles, or tapered side profiles.

In some embodiments, nanostructured layers 1742a and 1742b can include semiconductor materials similar to or different from substrate 104. In some embodiments, nanostructured layers 1742a and 1742b can include Si, SiAs, silicon phosphide, SiC, SiCP, SiGe, silicon germanium boron, germanium boron, silicon germanium tin boron, a III-V semiconductor compound, or other suitable semiconductor materials. Though rectangular cross-sections of nanostructured layers 1742a and 1742b are shown, nanostructured layers 1742 and 1742b can have cross-sections of other geometric shapes (e.g., circular, elliptical, triangular, or polygonal). In some embodiments, each layer of nanostructured layers 1742a and 1742b can have a thickness of about 3 nm to about 8 nm. In some embodiments, each layer of nanostructured layers 1742a and 1742b can have a width of about 5 nm to about 100 nm along an X-axis. In some embodiments, a distance between adjacent nanostructured layers 1742a and between adjacent nanostructured layers 1742b along a Z-axis can be about 3 nm to about 12 nm. In some embodiments, the number of nanostructured layers 1742a and 1742b in each stack can be 1, 2, 3, 4, 5, or 6.

In some embodiments, gate structures 1712a and 1712b can include (i) interfacial oxide (IL) layers 1724 disposed on nanostructured layers 1742a and 1742b, and (ii) high-k (HK) gate dielectric layers 1726 disposed on IL layers 1724. In some embodiments, IL layers 1724 can include silicon oxide (SiO₂), silicon germanium oxide (SiGeOₓ), or germanium oxide (GeOₓ). In some embodiments, HK gate dielectric layers 1726 can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). In some embodiments, gate structures 1712a and 1712b can further include conductive layer 1728. Conductive layer 1728 can be a multi-layered structure. The different layers of conductive layer 1728 are not shown for simplicity. Each of conductive layers 1728 can include a WFM layer disposed on HK dielectric layer 1726 and a gate metal fill layer on the WFM layer. In some embodiments, the WFM layers can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for n-type GAA FET 1702a or 1702b. In some embodiments, the WFM layers can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu) for p-type GAA FET 1702a or 1702b. The gate metal fill layers can include a suitable conductive material, such as tungsten (W), Ti, silver (Ag), ruthenium (Ru), molybdenum (Mo), copper (Cu), cobalt (Co), Al, iridium (Ir), nickel (Ni), metal alloys, and a combination thereof.

In some embodiments, gate structures 1712a and 1712b can be electrically isolated from adjacent S/D regions 1710a and 1710b, respectively, by inner spacers 1748. In some embodiments, gate structures 1712b can be electrically isolated from adjacent S/D contact structures 1720b by gate spacers 1714.

In some embodiments, S/D region 1710a can also be referred to as bottom S/D region 1710a. In some embodiments, S/D region 1710a can have a bottom surface in contact with the top surface of fin base 1706, as shown in FIG. 17A. In some embodiments, S/D region 1710a can have the bottom surface coplanar with a bottom surface of gate structures 1712a. In some embodiments, S/D region 1710a can have a side surface in contact with one or more nanostructured layers 1742a. In some embodiments, S/D region 1710a can have a top surface in contact with ESL 1717a. In some embodiments, S/D region 1710a can have the top surface lower than a bottom surface of nanostructured layer 1742a in contact with channel isolation layer 1746. In some embodiments, S/D region 1710a can include an epitaxially-grown p-type semiconductor material and can also be referred to as p-type S/D regions 1710a. In some embodiments, S/D region 1710a can include Si, SiB, SiAl, SiGa, SiIn, Ge, GeB, GeAl, GeGa, GeIn, Sn, SnB, SnAl, SnGa, SnIn, SiC, SiCB, SiCAl, SiCGa, SiCIn, SiGe, SiGeB, SiGeAl, SiGeGa, SiGeIn, SiSn, SiSnB, SiSnAl, SiSnGa, SiSnIn, SiGeC, SiGeCB, SiGeCAl, SiGeCGa, SiGeCIn, SiGeSn, SiGeSnB, SiGeSnAl, SiGeSnGa, SiGeSnIn, GeSn, GeSnB, GeSnAl, GeSnGa, GeSnIn, or a combination thereof. In some embodiments, S/D region 1710a can have a height of about 10 nm to about 100 nm.

In some embodiments, S/D region 1710b can also be referred to as top S/D region 1710b. In some embodiments, S/D region 1710b can have a bottom surface in contact with a top surface of ILD layer 1718a. In some embodiments, S/D region 1710b can have a top surface coplanar with a topmost surface of nanostructured layers 1742b. In some embodiments, S/D region 1710b can have a side surface in contact with one or more nanostructured layers 1742b. In some embodiments, S/D region 1710b can have a bottom surface higher than a top surface of nanostructured layer 1742b in contact with nanostructured isolation layer 1946. In some embodiments, S/D region 1710b can include an epitaxially-grown n-type semiconductor material and can also be referred to as n-type S/D region 1710b. In some embodiments, S/D region 1710b can include Si, SiP, SiAs, SiSb, SiBi, Ge, GeP, GeAs, GeSb, GeBi, Sn, SnP, SnAs, SnSb, SnBi, SiC, SiCP, SiCAs, SiCSb, SiCBi, SiGe, SiGeP, SiGeAs, SiGeSb, SiGeBi, SiSn, SiSnP, SiSnAs, SiSnSb, SiSnBi, SiGeC, SiGeCP, SiGeCAs, SiGeCSb, SiGeCBi, SiGeSn, SiGeSnP, SiGeSnAs, SiGeSnSb, SiGeSnBi, GeSn, GeSnP, GeSnAs, GeSnSb, GeSnBi, or a combination thereof. In some embodiments, S/D region 1710b can have a height of about 10 nm to about 100 nm.

Referring to FIG. 17B, S/D contact structure 1720b can be referred to as front-side S/D contact structure 1720b. In some embodiments, S/D contact structure 1720b can include a silicide layer 1734b and a contact plug 1736b disposed on silicide layer 1734b. In some embodiments, silicide layer 1734b can include titanium silicide (TiₓSi_{y}), tantalum silicide (TaₓSi), molybdenum silicide (MoₓSi_{y}), nickel silicide (NiₓSi_{y}), cobalt silicide (CoₓSi_{y}), tungsten silicide (WₓSi_{y}), or a combination thereof. In some embodiments, contact plug 1736b can include conductive materials, such as cobalt (Co), tungsten (W), ruthenium (Ru), iridium (Ir), nickel (Ni), osmium (Os), rhodium (Rh), aluminum (Al), molybdenum (Mo), copper (Cu), zirconium (Zr), stannum (Sn), silver (Ag), gold (Au), zinc (Zn), cadmium (Cd), and a combination thereof.

In some embodiments, front-side S/D contact structure 1720b can be electrically connected to power supplies and/or other active devices through front-side interconnect structure (not shown) formed on GAA FET 1702b.

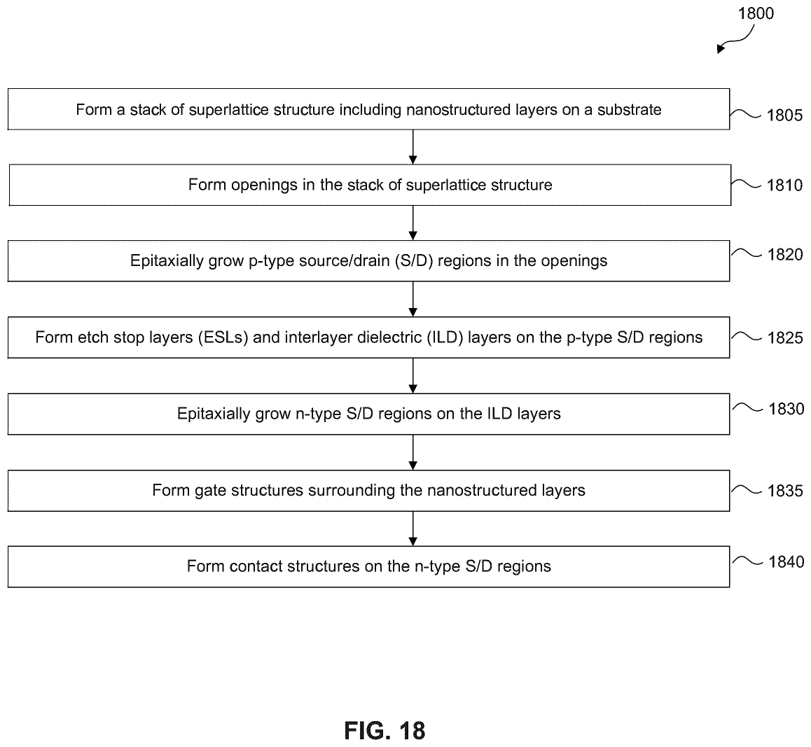

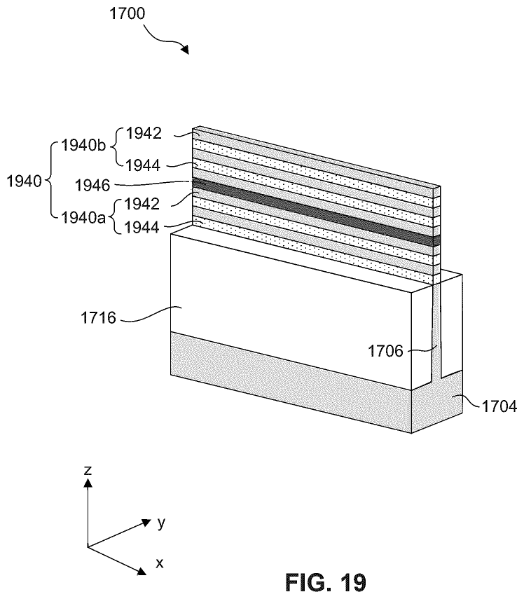

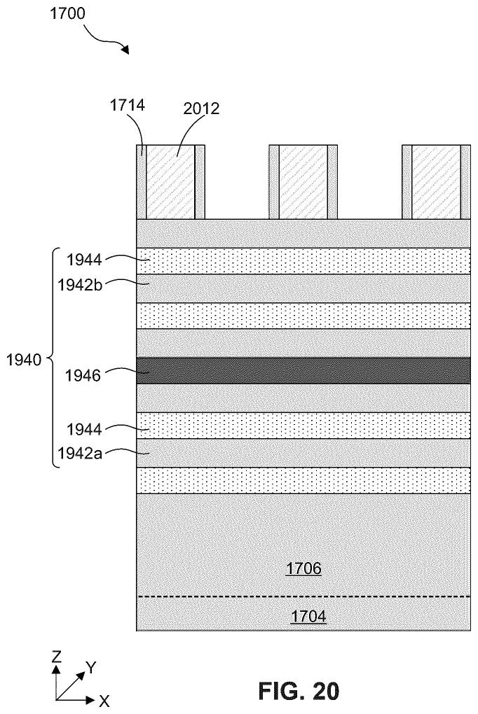

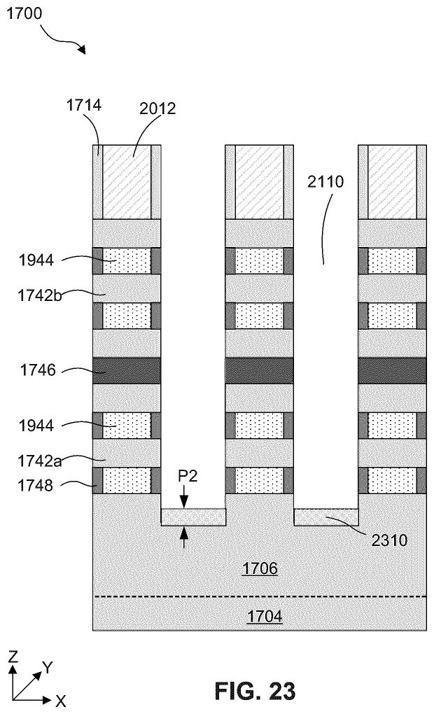

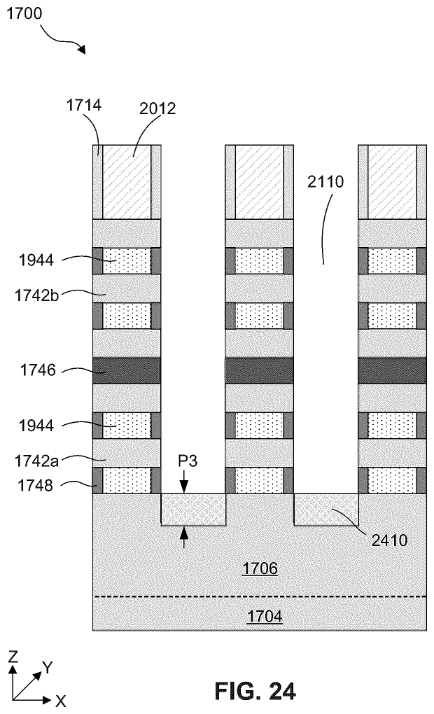

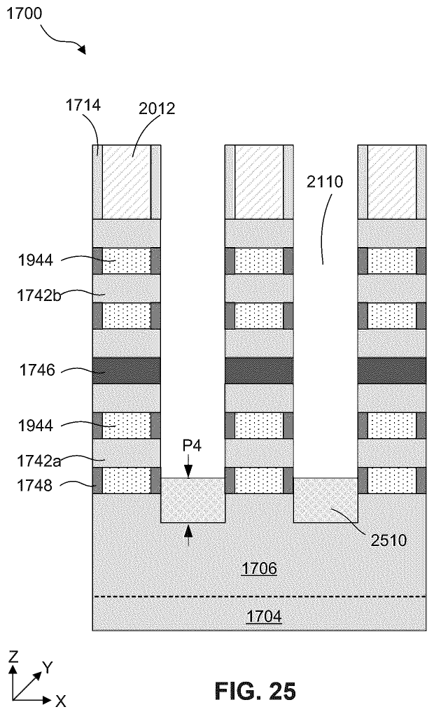

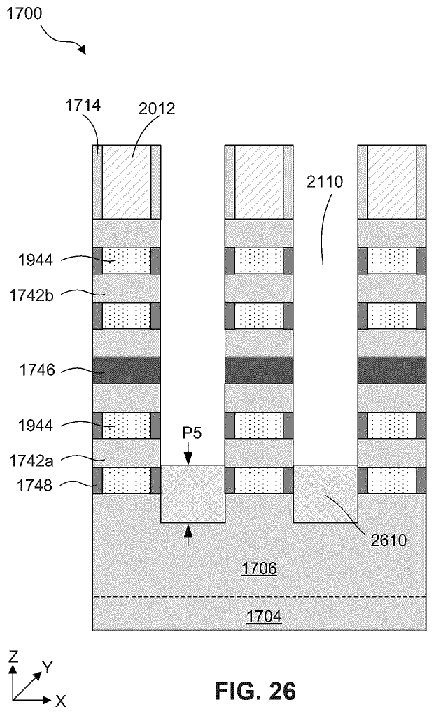

FIG. 18 is a flow diagram of an example method 1800 for forming CFET 1700 shown in FIGS. 17A and 17B, according to some embodiments. For illustrative purposes, the operations illustrated in FIG. 18 will be described with reference to the example fabrication process for fabricating CFET 1700 as illustrated in FIGS. 19-33. FIG. 19 is an isometric view of CFET 1700 at various stages of fabrication, according to some embodiments. FIGS. 20-33 are cross-sectional views of CFET 1700 along line A-A of FIG. 17A at various stages of fabrication, according to some embodiments. Operations can be performed in a different order or not performed depending on specific applications. It should be noted that method 1800 may not produce a complete CFET 1700. Accordingly, it is understood that additional processes can be provided before, during, and after method 1800, and that some other processes may only be briefly described herein. Elements in FIGS. 19-33 with the same annotations as elements in FIGS. 17A and 17B are described above.

Referring to FIG. 18, in operation 1805, a stack of superlattice structures including nanostructured layers is formed on a fin base. For example, as shown in FIG. 19, a stack of superlattice structures 1940 is formed on fin base 1706. In some embodiments, forming stack of superlattice structures 1940 can include forming first and second superlattice structures 1940a and 1940b and a nanostructured isolation layer 1946 disposed between first and second superlattice structures 1940a and 1940b.

Forming each of superlattice structures 1940a and 1940b can include forming nanostructured layers 1942 and 1944 alternatingly. In some embodiments, forming nanostructured layers 1942 and 1944 can include forming nanostructured layers 1942 and 1944 having the same crystallographic orientation as fin base 1706. In some embodiments, forming each of nanostructured layers 1942 can include depositing a layer of Si, and forming each of nanostructured layers 1944 can include depositing a layer of SiGe. Nanostructured layers 1942 can form nanostructured layers 1742a and 1742b in subsequent processing. Nanostructured isolation layer 1946 can form channel isolation layer 1746 in subsequent processing. In some embodiments, the formation of stack of superlattice structures 1940 can include epitaxially growing the materials of nanostructured layers 1942 and 1944 and depositing the material of nanostructured isolation layer 1946 on substrate 1704, followed by a photolithography process and an etching process.

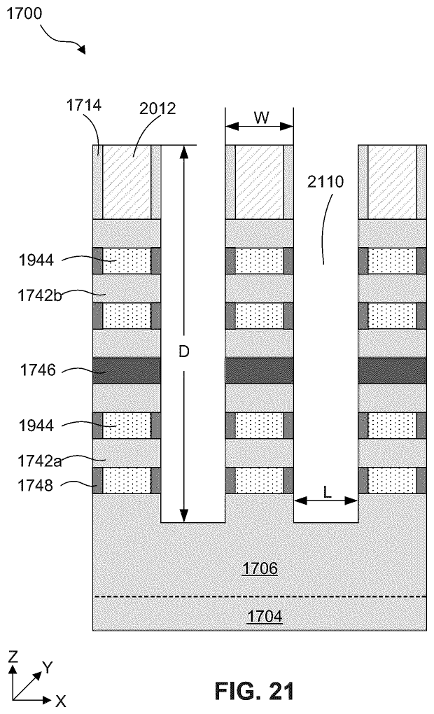

Referring to FIG. 18, in operation 1810, openings are formed in the stack of superlattice structures. For example, as described with reference to FIGS. 20 and 21, openings 2110 are formed in stack of superlattice structures 1940. In some embodiments, forming openings 2110 can include (i) forming polysilicon structures 2012 on stack of superlattice structures 1940, as shown in FIG. 20, and (ii) removing portions of stack of superlattice structures 1940 uncovered by polysilicon structures 2012 to form openings 2110, as shown in FIG. 21. In some embodiments, forming polysilicon structures 2012 can include depositing a layer of polysilicon on stack of superlattice structures 1940 and patterning the layer of polysilicon to form polysilicon structures 2012. In some embodiments, gate spacers 1714 can be formed on side surfaces of polysilicon structures 2012. In some embodiments, removing portions of stack of superlattice structures 1940 can include removing portions of nanostructured layers 1942 and 1944 and nanostructured isolation layer 1946 that are not covered by polysilicon structures 2012. In some embodiments, forming openings 2110 can include recessing portions of fin base 1706 not covered by polysilicon structures 2012. In some embodiments, openings 2110 can be formed to have a CD (a width L) of about 5 nm to about 30 nm, as shown in FIG. 21. In some embodiments, openings 2110 can be formed to have an AR (a ratio between a depth D and width L of openings 2110) greater than about 5, as shown in FIG. 21.

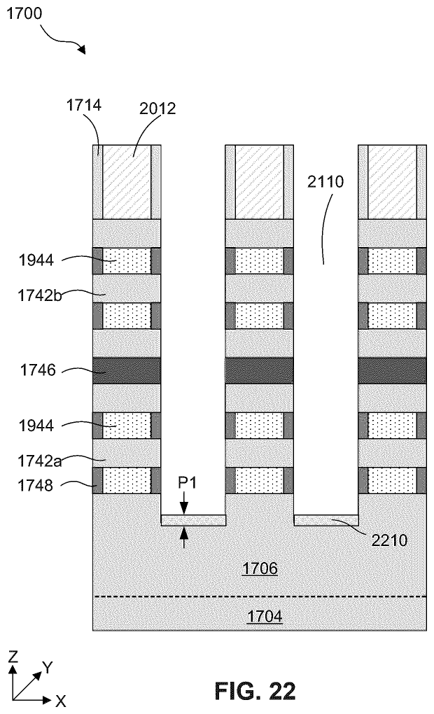

Referring to FIG. 18, in operation 1820, p-type S/D regions are epitaxially grown in the openings. For example, as described with reference to FIGS. 22-27, a p-type semiconductor material can be epitaxially grown in openings 2110. In some embodiments, the p-type semiconductor material can be epitaxially grown from recessed fin base 1706 and/or nanostructured layers 1742a exposed on side surfaces of openings 2110. In some embodiments, epitaxially growing the p-type semiconductor material can include epitaxially growing the p-type semiconductor material having the same crystallographic orientation as fin base 1706 and/or nanostructured layers 1742a. In some embodiments, epitaxially growing the p-type semiconductor material can include epitaxially growing the p-type semiconductor material along the [100] or [110] crystallographic orientation. In some embodiments, the p-type semiconductor material can be epitaxially grown using a PECVD process at a temperature of about 500° C. or below. For example, as described with reference to FIGS. 9B, 10B, 13B, and 14B, the p-type semiconductor material can be epitaxially grown using processes 900B, 1000B, 1300B, or 1400B.

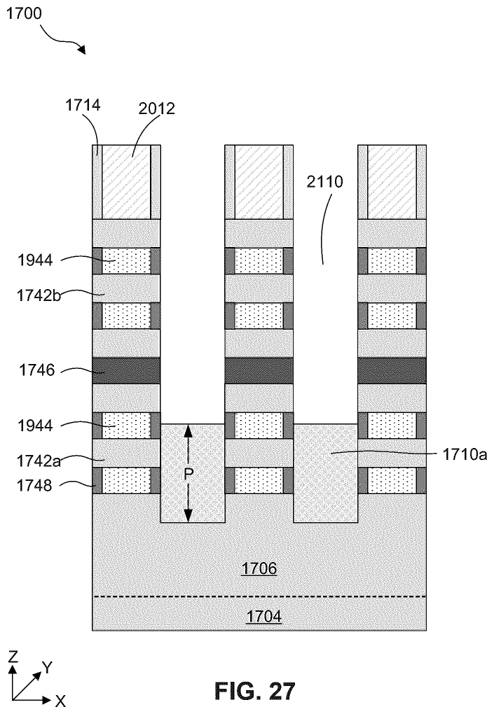

Referring to FIGS. 9B and 27, in some embodiments, the p-type semiconductor material can be epitaxially grown in openings 2110 to form p-type S/D regions 1710a, using process 900B. The discussion of epitaxially growing p-type semiconductor material in S/D opening 710 using process 900B in operation 220 applies to epitaxially growing p-type semiconductor material in openings 2110 using process 900B in operation 1820, unless mentioned otherwise. In some embodiments, forming p-type S/D regions 1710a can include providing a plasma, a carrier gas, a precursor gas, an etching gas, and a dopant precursor gas in a PECVD chamber. In some embodiments, the dopant precursor gas can be a p-type dopant precursor gas. In some embodiments, the process of forming p-type S/D regions 1710a can start at time T₁ and end at time T₂, as shown in FIG. 9B. In some embodiments, between time T₁ and time T₂, plasma condition 908 can be ‘on’, and etching gas flow rate 904, precursor gas flow rate 906, and dopant precursor gas flow rate 910 can be maintained at non-zero value E1, P1, and D1, respectively. In some embodiments, carrier gas flow rate 902 can be maintained at non-zero value starting before time T₁ and ending after time T₂. In some embodiments, a processing time T₂−T₁ can be controlled such that p-type S/D regions 1710a can have a height P, as shown in FIG. 27. In some embodiments, forming p-type S/D regions 1710a can include forming the top surface of p-type S/D regions 1710a lower than the bottom surface of nanostructured layer 1742a in contact with nanostructured isolation layer 1946, as shown in FIG. 27.

Referring to FIGS. 10B and 27, in some embodiments, the p-type semiconductor material can be epitaxially grown in openings 2110 to form p-type S/D regions 1710a, using process 1000B. The discussion of epitaxially growing p-type semiconductor material in S/D opening 710 using process 1000B in operation 220 applies to epitaxially growing p-type semiconductor material in openings 2110 using process 1000B in operation 1820, unless mentioned otherwise. The discussion of forming p-type S/D regions 1710a using process 900B applies to forming p-type S/D regions 1710a using process 1000B, unless mentioned otherwise. In some embodiments, forming p-type S/D regions 1710a using process 1000B can include varying both precursor gas flow rate 1006 and dopant precursor gas flow rate 1010 in gas flow cycles. For example, as shown in FIG. 10B, during the first phase of each gas flow cycle, precursor gas flow rate 1006 and dopant precursor gas flow rate 1010 can be maintained at non-zero values P1 and D1, respectively. During the second phase of each gas flow cycle, precursor gas flow rate 1006 and dopant precursor gas flow rate 1010 can be maintained at zero.

Referring to FIGS. 13B and 27, in some embodiments, the p-type semiconductor material can be epitaxially grown in openings 2110 to form p-type S/D regions 1710a, using process 1300B. The discussion of epitaxially growing p-type semiconductor material in S/D opening 710 using process 1300B in operation 220 applies to epitaxially growing p-type semiconductor material in openings 2110 using process 1300B in operation 1820, unless mentioned otherwise. The discussion of forming p-type S/D regions 1710a using process 1000B applies to forming p-type S/D regions 1710a using process 1300B, unless mentioned otherwise. In some embodiments, forming p-type S/D regions 1710a using process 1300B can include varying etching gas flow rate 1304, precursor gas flow rate 1006, and dopant precursor gas flow rate 1010 in gas flow cycles. For example, as shown in FIG. 13B, during the first phase of each gas flow cycle, etching gas flow rate 1304 can be maintained at zero, and precursor gas flow rate 1006 and dopant precursor gas flow rate 1010 can be maintained at non-zero values P1 and D1. During the second phase of each gas flow cycle, etching gas flow rate 1304 can be maintained at non-zero value E1, and precursor gas flow rate 1006 and dopant precursor gas flow rate 1010 can be maintained at zero.

Referring to FIGS. 14B and 27, in some embodiments, the p-type semiconductor material can be epitaxially grown in openings 2110 to form p-type S/D regions 1710a, using process 1400B. The discussion of epitaxially growing p-type semiconductor material in S/D opening 710 using process 1400B in operation 220 applies to epitaxially growing p-type semiconductor material in openings 2110 using process 1400B in operation 1820, unless mentioned otherwise. The discussion of forming p-type S/D regions 1710a using process 1300B applies to forming p-type S/D regions 1710a using process 1400B, unless mentioned otherwise. In some embodiments, forming p-type S/D regions 1710a using process 1400B can include varying plasma condition 1408, etching gas flow rate 1304, precursor gas flow rate 1006, and dopant precursor gas flow rate 1010 in gas flow cycles. For example, as shown in FIG. 14B, during the first phase of each gas flow cycle, plasma condition 1408 can be ‘off’, etching gas flow rate 1304 can be maintained at zero, and precursor gas flow rate 1006 and dopant precursor gas flow rate 1010 can be maintained at non-zero values P1 and D1. During the second phase of each gas flow cycle, plasma condition 1408 can be ‘on’, etching gas flow rate 1304 can be maintained at non-zero value E1, and precursor gas flow rate 1006 and dopant precursor gas flow rate 1010 can be maintained at zero.

In some embodiments, forming p-type S/D regions 1710a using process 1000B, 1300B, or 1400B can include multiple gas flow cycles. In some embodiments, after the first, second, third, fourth, and fifth gas flow cycles of process 1000B, 1300B, or 1400B, p-type S/D regions 2210, 2310, 2410, 2510, and 2610 having height P1, P2, P3, P4, and P5 can be formed in openings 2110, as shown in FIGS. 22, 23, 24, 25, and 26, respectively. In some embodiments, after the multiple gas flow cycles of process 1000B, 1300B, or 1400B are completed at time T₂, p-type S/D regions 1710a having height P can be completely formed in openings 2110, as shown in FIG. 27. Although FIGS. 22-27 show more than five gas flow cycles to form p-type S/D regions 1710a, any number of cycles can be used to form p-type S/D regions 1710a, according to some embodiments.

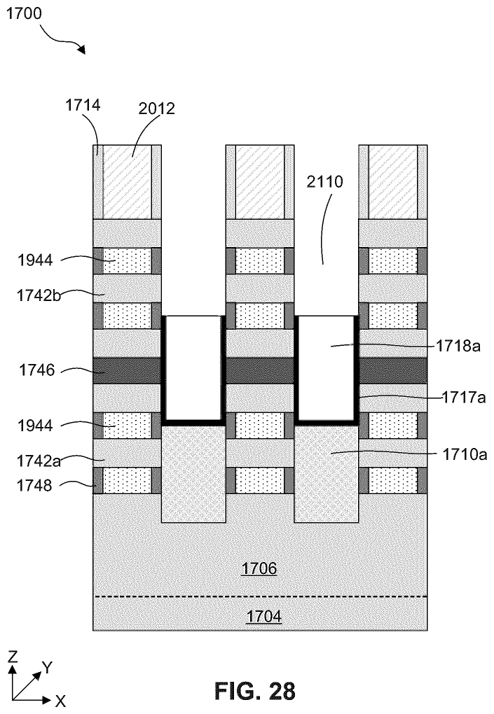

Referring to FIG. 18, in operation 1825, ESL and ILD layer are formed in the openings and on the p-type S/D regions. For example, as described with reference to FIG. 28, ESL 1717a can be formed on p-type S/D regions 1710a and on side surfaces of openings 2110, and ILD layer 1718 can be formed on ESL 1717a. In some embodiments, forming ESL 1717a and ILD layer 1718 can include depositing one or more insulating materials in openings 2110, as shown in FIG. 28. In some embodiments, forming ESL 1717a and ILD layer 1718 can include recessing portions of ESL 1717a and ILD layer 1718 in openings 2110. In some embodiments, forming ESL 1717a and ILD layer 1718 can include forming a top surface of ILD layer 1718 higher than the top surface nanostructured layer 1742b in contact with nanostructured isolation layer 1946, as shown in FIG. 28.

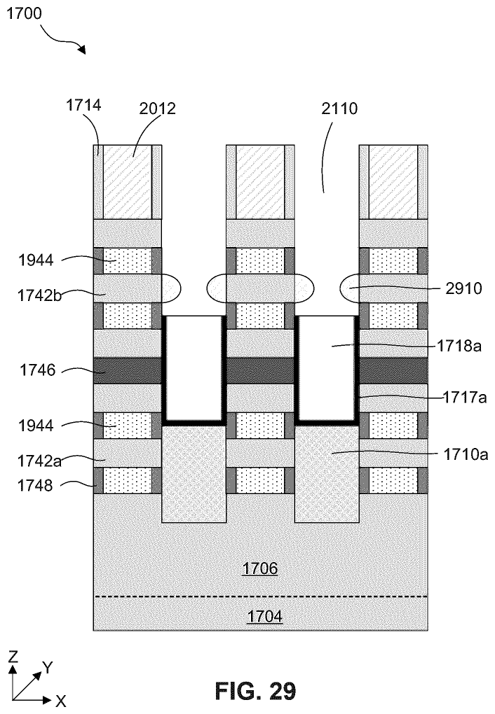

Referring to FIG. 18, in operation 1830, n-type S/D regions are epitaxially grown on the ILD layers. For example, as described with reference to FIGS. 29-31, an n-type semiconductor material can be epitaxially grown in openings 2110. In some embodiments, the n-type semiconductor material can be epitaxially grown from side surfaces of nanostructured layers 1742b exposed on side surfaces of openings 2110. During the epitaxial growth of the n-type semiconductor material, the n-type semiconductor material can extend laterally and vertically to substantially fill openings 2110. The n-type semiconductor material does not grow epitaxially on the non-semiconductor material of inner spacers 1748 and ILD layers 1718a. As a result, in some embodiments, air gaps can be formed at the interfaces between the n-type semiconductor material and inner spacers 1748 and between n-type semiconductor material and ILD layer 1718a. In some embodiments, epitaxially growing the n-type semiconductor material can include epitaxially growing the n-type semiconductor material having the same crystallographic orientation as nanostructured layers 1742b. In some embodiments, epitaxially growing the n-type semiconductor material can include epitaxially growing the n-type semiconductor material along the [100] or [110] crystallographic orientation. In some embodiments, the n-type semiconductor material can be epitaxially grown using a PECVD process at a temperature of about 500° C. or below. For example, as described with reference to FIGS. 9B, 10B, 13B, and 14B, the n-type semiconductor material can be epitaxially grown using processes 900B, 1000B, 1300B, or 1400B.

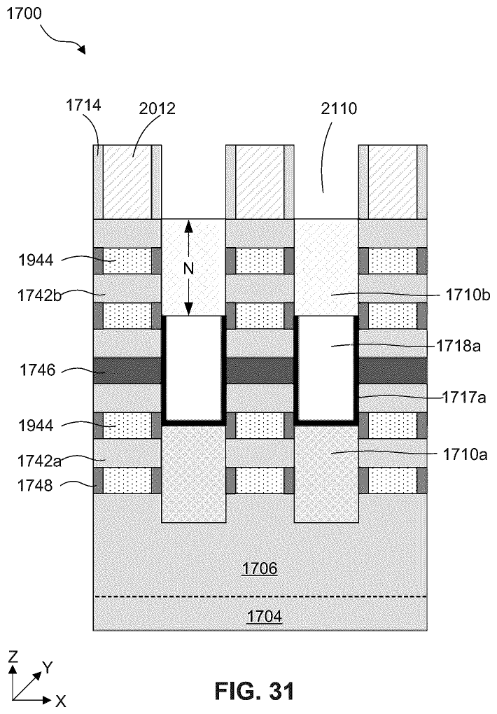

Referring to FIGS. 9B and 31, in some embodiments, the n-type semiconductor material can be epitaxially grown in openings 2110 to form n-type S/D regions 1710b, using process 900B. The discussion of epitaxially growing n-type semiconductor material in S/D opening 710 using process 900B in operation 220 applies to epitaxially growing n-type semiconductor material in openings 2110 using process 900B in operation 1830, unless mentioned otherwise. In some embodiments, forming n-type S/D regions 1710b can include providing a plasma, a carrier gas, a precursor gas, an etching gas, and a dopant precursor gas in a PECVD chamber. In some embodiments, the dopant precursor gas can be an n-type dopant precursor gas. In some embodiments, the process of forming n-type S/D regions 1710b can start at time T₁ and end at time T₂, as shown in FIG. 9B. In some embodiments, between time T₁ and time T₂, plasma condition 908 can be ‘on’, and etching gas flow rate 904, precursor gas flow rate 906, and dopant precursor gas flow rate 910 can be maintained at non-zero value E1, P1, and D1, respectively. In some embodiments, carrier gas flow rate 902 can be maintained at non-zero value starting before time T₁ and ending after time T₂. In some embodiments, a processing time T₂−T₁ can be controlled such that n-type S/D regions 1710b can have a height N, as shown in FIG. 31. In some embodiments, forming n-type S/D regions 1710b can include forming the top surface of n-type S/D regions 1710b coplanar with the topmost surface of nanostructured layers 1742b, as shown in FIG. 31.

Referring to FIGS. 10B and 31, in some embodiments, the n-type semiconductor material can be epitaxially grown in openings 2110 to form n-type S/D regions 1710b, using process 1000B. The discussion of epitaxially growing n-type semiconductor material in S/D opening 710 using process 1000B in operation 220 applies to epitaxially growing n-type semiconductor material in openings 2110 using process 1000B in operation 1830, unless mentioned otherwise. The discussion of forming n-type S/D regions 1710b using process 900B applies to forming n-type S/D regions 1710b using process 1000B, unless mentioned otherwise. In some embodiments, forming n-type S/D regions 1710b using process 1000B can include varying both precursor gas flow rate 1006 and dopant precursor gas flow rate 1010 in gas flow cycles. For example, as shown in FIG. 10B, during the first phase of each gas flow cycle, precursor gas flow rate 1006 and dopant precursor gas flow rate 1010 can be maintained at non-zero values P1 and D1, respectively. During the second phase of each gas flow cycle, precursor gas flow rate 1006 and dopant precursor gas flow rate 1010 can be maintained at zero.

Referring to FIGS. 13B and 31, in some embodiments, the n-type semiconductor material can be epitaxially grown in openings 2110 to form n-type S/D regions 1710b, using process 1300B. The discussion of epitaxially growing n-type semiconductor material in S/D opening 710 using process 1300B in operation 220 applies to epitaxially growing n-type semiconductor material in openings 2110 using process 1300B in operation 1830, unless mentioned otherwise. The discussion of forming n-type S/D regions 1710b using process 1000B applies to forming n-type S/D regions 1710b using process 1300B, unless mentioned otherwise. In some embodiments, forming n-type S/D regions 1710b using process 1300B can include varying etching gas flow rate 1304, precursor gas flow rate 1006, and dopant precursor gas flow rate 1010 in gas flow cycles. For example, as shown in FIG. 13B, during the first phase of each gas flow cycle, etching gas flow rate 1304 can be maintained at zero, and precursor gas flow rate 1006 and dopant precursor gas flow rate 1010 can be maintained at non-zero values P1 and D1. During the second phase of each gas flow cycle, etching gas flow rate 1304 can be maintained at non-zero value E1, and precursor gas flow rate 1006 and dopant precursor gas flow rate 1010 can be maintained at zero.

Referring to FIGS. 14B and 31, in some embodiments, the n-type semiconductor material can be epitaxially grown in openings 2110 to form n-type S/D regions 1710b, using process 1400B. The discussion of epitaxially growing n-type semiconductor material in S/D opening 710 using process 1400B in operation 220 applies to epitaxially growing n-type semiconductor material in openings 2110 using process 1400B in operation 1820, unless mentioned otherwise. The discussion of forming n-type S/D regions 1710b using process 1300B applies to forming n-type S/D regions 1710b using process 1400B, unless mentioned otherwise. In some embodiments, forming n-type S/D regions 1710b using process 1400B can include varying plasma condition 1408, etching gas flow rate 1304, precursor gas flow rate 1006, and dopant precursor gas flow rate 1010 in gas flow cycles. For example, as shown in FIG. 14B, during the first phase of each gas flow cycle, plasma condition 1408 can be ‘off’, etching gas flow rate 1304 can be maintained at zero, and precursor gas flow rate 1006 and dopant precursor gas flow rate 1010 can be maintained at non-zero values P1 and D1. During the second phase of each gas flow cycle, plasma condition 1408 can be ‘on’, etching gas flow rate 1304 can be maintained at non-zero value E1, and precursor gas flow rate 1006 and dopant precursor gas flow rate 1010 can be maintained at zero.

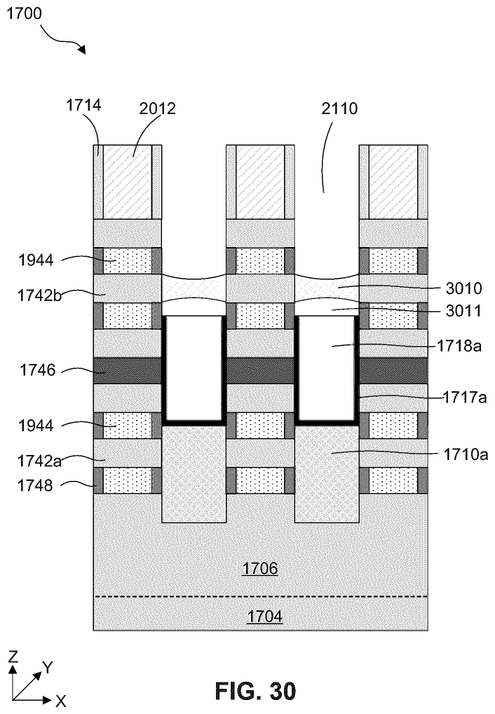

In some embodiments, forming n-type S/D regions 1710b using process 1000B, 1300B, or 1400B can include multiple gas flow cycles. In some embodiments, after the first gas flow cycle of process 1000B, 1300B, or 1400B is completed, n-type S/D regions 2910 can be formed in openings 2110, as shown in FIG. 29. In some embodiments, after the second gas flow cycle of process 1000B, 1300B, or 1400B is completed, n-type S/D regions 3010 can be formed in openings 2110, as shown in FIG. 30. In some embodiments, air gaps 3011 can be formed between n-type S/D regions 3010 and ILD layer 1718a. In some embodiments, after the multiple gas flow cycles of process 1000B, 1300B, or 1400B are completed at time T₂, n-type S/D regions 1710b having height N can be completely formed in openings 2110, as shown in FIG. 31.

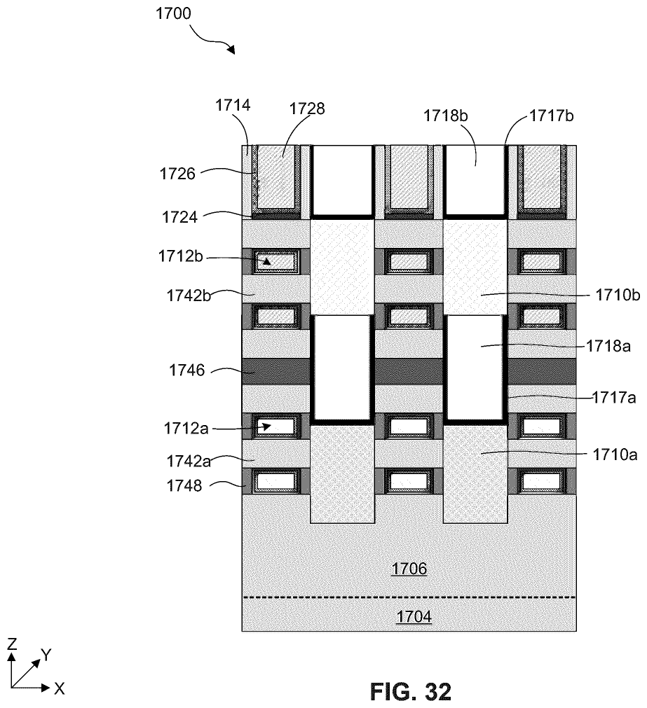

Referring to FIG. 18, in operation 1835, gate structures are formed to surround the nanostructured layers. For example, as described with reference to FIG. 32, gate structures 1712a, referred to as “bottom gate structures,” are formed to surround nanostructured layers 1742a, and gate structures 1712b, referred to as “top gate structures,” are formed to surround nanostructured layers 1742b.

The formation of gate structures 1712a and 1712b can include sequential operations of (i) removing nanostructured layers 1944 and polysilicon structures 2012, (ii) forming 1L layers 1724 on exposed regions of nanostructured layers 1742a and 1742b, (iii) depositing HK gate dielectric layers 1726 on IL layers 1724, and (iv) depositing conductive layers 1728 on HK gate dielectric layers 1726, as shown in FIG. 32. ESLs 1717b and ILD layers 1718b can be formed in openings after forming gate structures 1712a and 1712b, as shown in FIG. 32.

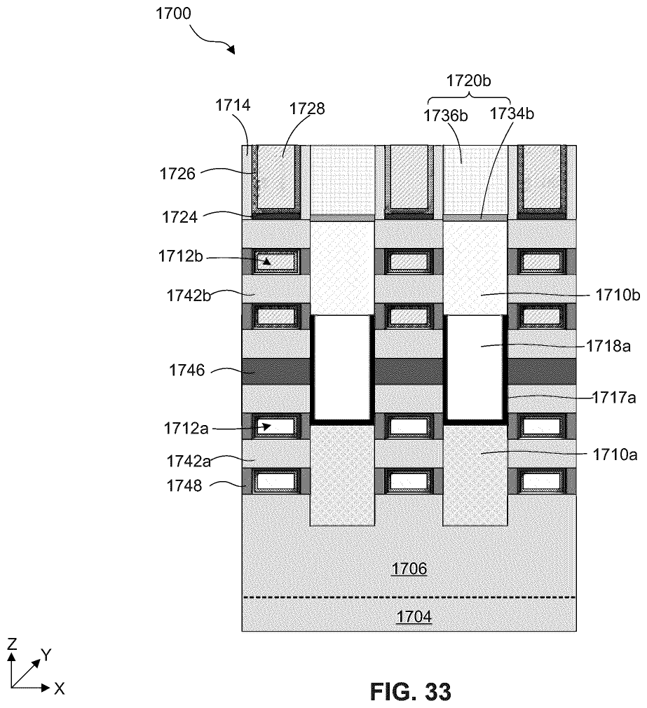

Referring to FIG. 18, in operation 1840, contact structures are formed on the n-type S/D regions. For example, as described with reference to FIG. 33, front-side S/D contact structures 1720b are formed on front-side surfaces of top S/D regions 1710b. In some embodiments, the formation of front-side S/D contact structures 1720b can include sequential operations of (i) removing portions of ILD layers 1718b and portions of ESLs 1717b to expose the front-side surfaces of top S/D regions 1710b, (ii) forming silicide layers 1734b on the front-side surfaces of top S/D regions 1710b, and (iii) forming contact plugs 1736b on silicide layers 1734b, as shown in FIG. 33.

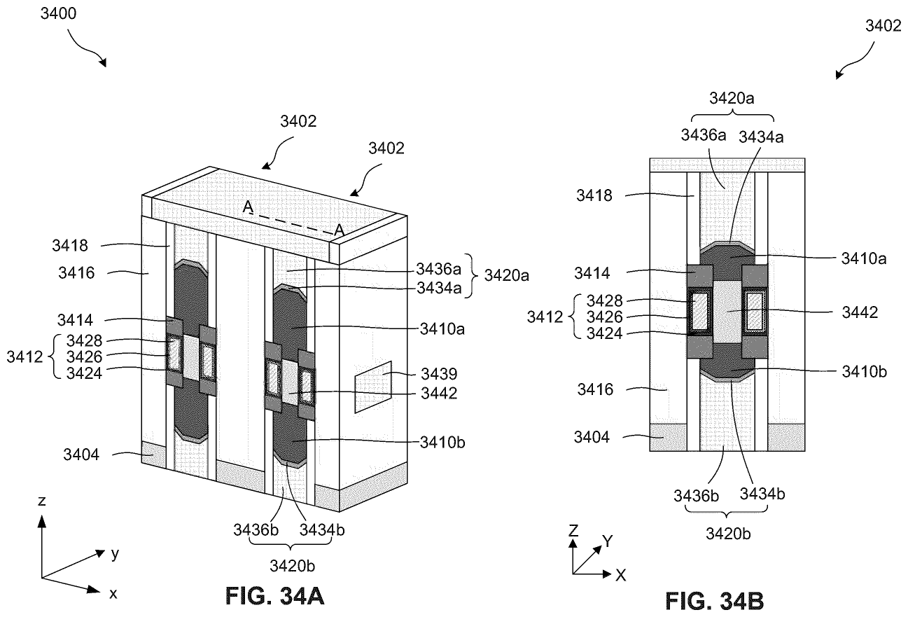

FIG. 34A illustrates an isometric view of a semiconductor device 3400, according to some embodiments. FIG. 34B illustrates a cross-sectional view of semiconductor device 3400 along line A-A, according to some embodiments. The discussion of elements with the same annotations applies to each other, unless mentioned otherwise.

Referring to FIGS. 34A and 34B, semiconductor device 3400 can include (i) a substrate 3404, (ii) STI regions 3416 disposed on substrate 3404, and (iii) VFETs 3402 disposed on substrate 3404 and adjacent to STI regions 3416. In some embodiments, substrate 3404 can be a semiconductor material, such as silicon, germanium (Ge), silicon germanium (SiGe), a silicon-on-insulator (SOI) structure, and a combination thereof. Further, substrate 3404 can be doped with p-type dopants (e.g., boron, indium, aluminum, or gallium) or n-type dopants (e.g., phosphorus or arsenic). In some embodiments, a top surface of substrate 3404 can be normal to [100] or [110] crystallographic orientation. In some embodiments, STI regions 3416 can include an insulating material, such as silicon oxide, silicon nitride (SiN), silicon carbon nitride (SiCN), silicon oxycarbon nitride (SiOCN), and silicon germanium oxide.

In some embodiments, VFET 3402 can include (i) ILD layers 3418 disposed adjacent to STI regions 3416, (ii) a gate structure 3412 adjacent to ILD layers 3418, (iii) a vertical channel layer 3442 surrounded by gate structure 3412, (iii) S/D regions 3410a and 3410b disposed on top and bottom surfaces of vertical channel layer 3442, respectively, (iv) S/D contact structures 3420a and 3420b in contact with S/D regions 3410a and 3420b, respectively, (v) gate spacers 3414 disposed adjacent to gate structures 3412, and (vi) a gate contact structure 3439 disposed through STI regions 3416 and in contact with gate structures 3412. In some embodiments, VFET 3402 can have a p-type conductivity and can be referred to as p-type VFET 3402. In some embodiments, VFET 3402 can have an n-type conductivity and can be referred to as n-type VFET 3402.

In some embodiments, vertical channel layer 3442 can include semiconductor materials similar to or different from substrate 3404. In some embodiments, vertical channel layer 3442 can include Si, SiAs, SiP, SiC, SiCP, SiGe, Silicon Germanium Boron, Germanium Boron, Silicon-Germanium-Tin-Boron, a III-V semiconductor compound, or other suitable semiconductor materials. Though a rectangular cross-section of vertical channel layer 3442 is shown, vertical channel layer 3442 can have cross-sections of other geometric shapes (e.g., circular, elliptical, triangular, or polygonal).

In some embodiments, gate structure 3412 can have substantially equal gate lengths along a Z-axis. In some embodiments, gate structures 3412 can include (i) an IL layer 3424 disposed on vertical channel layers 3442, (ii) an HK gate dielectric layer 3426 disposed on IL layer 3424, and (iii) a conductive layer 3428. Conductive layer 3428 can include a multi-layered structure. The different layers of conductive layer 3428 are not shown for simplicity. Conductive layer 3428 can include a WFM layer disposed on HK dielectric layer 3426 and a gate metal fill layer disposed on the WFM layer. In some embodiments, the WFM layer can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for n-type VFET 3402. In some embodiments, the WFM layer can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu) for p-type VFET 3402. The gate metal fill layer can include a suitable conductive material, such as tungsten (W), Ti, silver (Ag), ruthenium (Ru), molybdenum (Mo), copper (Cu), cobalt (Co), Al, iridium (Ir), nickel (Ni), metal alloys, and a combination thereof. In some embodiments, gate structure 3412 can be electrically isolated from S/D regions 3410a and 3410b by gate spacers 3414.

In some embodiments, S/D regions 3410a and 3410b can also be referred to as top S/D region 3410a and bottom S/D regions 3410b, respectively. In some embodiments, S/D regions 3410a and 3410b can include an epitaxially-grown semiconductor material. In some embodiments, S/D regions 3410a and 3410b can include a p-type semiconductor material and can also be referred to as p-type S/D regions 3410a and 3410b. In some embodiments, p-type S/D regions 3410a and 3410b can include Si, SiB, SiAl, SiGa, SiIn, Ge, GeB, GeAl, GeGa, GeIn, Sn, SnB, SnAl, SnGa, SnIn, SiC, SiCB, SiCAl, SiCGa, SiCIn, SiGe, SiGeB, SiGeAl, SiGeGa, SiGeIn, SiSn, SiSnB, SiSnAl, SiSnGa, SiSnIn, SiGeC, SiGeCB, SiGeCAl, SiGeCGa, SiGeCIn, SiGeSn, SiGeSnB, SiGeSnAl, SiGeSnGa, SiGeSnIn, GeSn, GeSnB, GeSnAl, GeSnGa, GeSnIn, or a combination thereof. In some embodiments, S/D regions 3410a and 3410b can include an n-type semiconductor material and can also be referred to as n-type S/D regions 3410a and 3410b. In some embodiments, n-type S/D regions 3410a and 3410b can include Si, SiP, SiAs, SiSb, SiBi, Ge, GeP, GeAs, GeSb, GeBi, Sn, SnP, SnAs, SnSb, SnBi, SiC, SiCP, SiCAs, SiCSb, SiCBi, SiGe, SiGeP, SiGeAs, SiGeSb, SiGeBi, SiSn, SiSnP, SiSnAs, SiSnSb, SiSnBi, SiGeC, SiGeCP, SiGeCAs, SiGeCSb, SiGeCBi, SiGeSn, SiGeSnP, SiGeSnAs, SiGeSnSb, SiGeSnBi, GeSn, GeSnP, GeSnAs, GeSnSb, GeSnBi, or a combination thereof.

S/D contact structure 3420a can be referred to as front-side S/D contact structure 3420a and S/D contact structure 3420b can be referred to as back-side S/D contact structure 3420b. In some embodiments, S/D contact structure 3420a can include a silicide layer 3434a and a contact plug 3436a disposed on silicide layer 3434a. In some embodiments, S/D contact structure 3420b can include a silicide layer 3434b and a contact plug 3436b disposed on silicide layer 3434b. In some embodiments, silicide layers 3434a and 3434b can include titanium silicide (TiₓSi_{y}), tantalum silicide (TaₓSi), molybdenum silicide (MoₓSi_{y}), nickel silicide (NiₓSi_{y}), cobalt silicide (CoₓSi_{y}), tungsten silicide (WₓSi_{y}), or a combination thereof. In some embodiments, contact plugs 3436a and 3436b can include conductive materials, such as cobalt (Co), tungsten (W), ruthenium (Ru), iridium (Ir), nickel (Ni), osmium (Os), rhodium (Rh), aluminum (Al), molybdenum (Mo), copper (Cu), zirconium (Zr), stannum (Sn), silver (Ag), gold (Au), zinc (Zn), cadmium (Cd), and a combination thereof.

In some embodiments, front-side S/D contact structure 3420a can be electrically connected to power supplies and/or other active devices through front-side interconnect structure (not shown). In some embodiments, back-side S/D contact structure 3420b can be electrically connected to power supplies and/or other active devices through back-side interconnect structure (not shown). In some embodiments, S/D contact structures 3420a and 3420b can be electrically connected to each other.

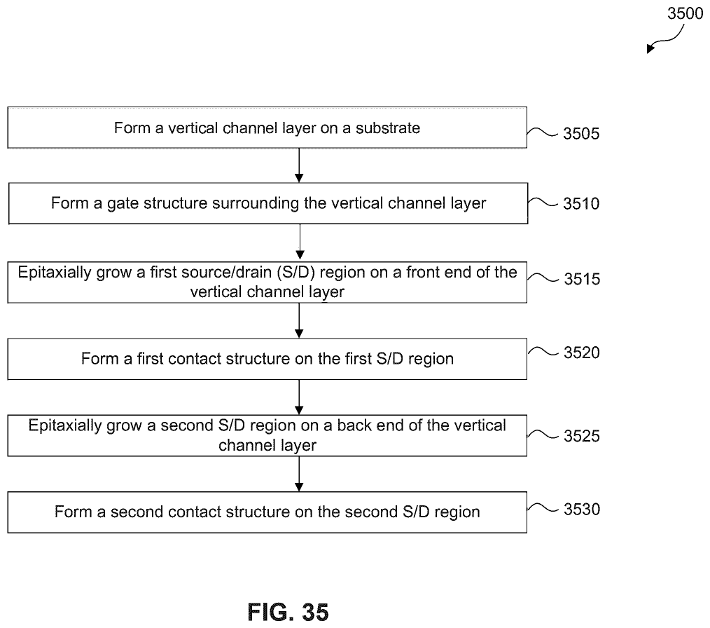

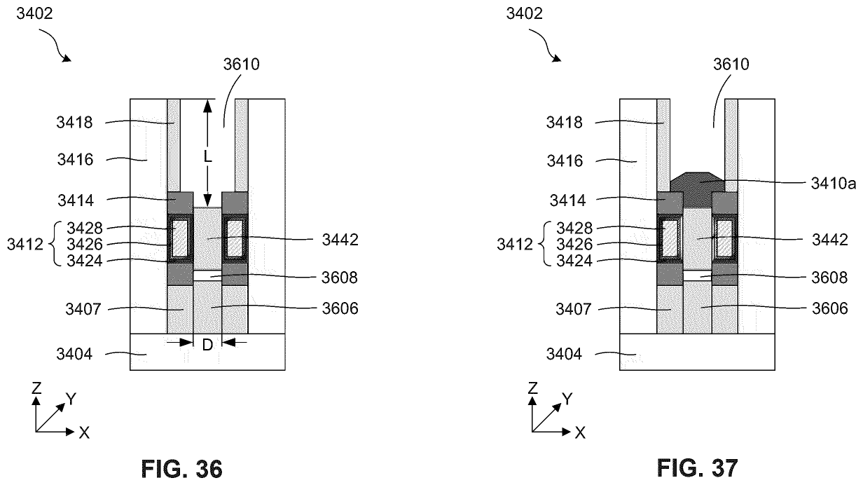

FIG. 35 is a flow diagram of an example method 3500 for fabricating semiconductor device 3400 shown in FIGS. 34A and 34B, according to some embodiments. For illustrative purposes, the operations illustrated in FIG. 35 will be described with reference to the example fabrication process for fabricating semiconductor device 3400 as illustrated in FIGS. 36-45, which are cross-sectional views of semiconductor device 3400 along line A-A of FIG. 34A at various stages of fabrication, according to some embodiments. Operations can be performed in a different order or not performed depending on specific applications. It should be noted that method 3500 may not produce a complete semiconductor device 3400. Accordingly, it is understood that additional processes can be provided before, during, and after method 3500, and that some other processes may only be briefly described herein. Elements in FIGS. 36-45 with the same annotations as elements in FIGS. 34A and 34B are described above.

In operation 3505, a vertical channel layer of a VFET is formed on a substrate. For example, as described with reference to FIG. 36, vertical channel layer 3442 of VFET 3402 is formed on substrate 3404. The formation of vertical channel layer 3442 can include sequential operations of (i) etching substrate 3404 to form a vertical structure 3606, (ii) forming a SiGe layer 3608 on vertical structure 3606, and (iii) forming vertical channel layer 3442 on SiGe layer 3608. In some embodiments, forming vertical channel layer 3442 can include controlling a width D of vertical channel layer 3442 (also referred to as a CD of vertical channel layer 3442) to be about 5 nm to about 30 nm. In some embodiments, forming vertical channel layer 3442 can include epitaxially growing vertical channel layer 3442 having a same crystallographic orientation as substrate 3404. In some embodiments forming vertical channel layer 3442 can include epitaxially growing vertical channel layer 3442 along the [100] or [110] crystallographic orientation.

After forming vertical channel layer 3442, a dielectric layer 3407 can be formed on substrate 3404 and adjacent to vertical structure 3606, and STI region 3416 can be formed on substrate 3404 and adjacent to dielectric layer 3407.

Referring to FIG. 35, in operation 3510, a gate structure is formed surrounding the vertical channel layer. For example, as shown in FIG. 36, gate structure 3412 is formed surrounding vertical channel layer 3442. After forming gate structure 3412, ILD layers 3418 can be deposited on gate structure 3412 and the side surfaces of STI regions 3416 to form an opening 3610. In some embodiments, forming opening 3610 can include controlling a vertical distance L between a top surface of vertical channel layer 3442 and a top surface of ILD layers 3418, as shown in FIG. 36. In some embodiments, forming opening 3610 can include controlling an AR (a ratio between L and D) to be greater than about 5.

Referring to FIG. 35, in operation 3515, a first S/D region is formed on front end of the vertical channel layer. For example, as described with reference to FIG. 37, S/D region 3410a is formed in opening 3610 and on vertical channel layer 3442. In some embodiments, forming S/D region 3410a can include epitaxially growing a p-type or n-type semiconductor material on vertical channel layer 3442. In some embodiments, epitaxially growing the p-type or n-type semiconductor material can include epitaxially growing the p-type or n-type semiconductor material having a same crystallographic orientation as vertical channel layer 3442. In some embodiments, epitaxially growing the p-type or n-type semiconductor material can include epitaxially growing the p-type or n-type semiconductor material along the [100] or [110] crystallographic orientation. In some embodiments, the p-type or n-type semiconductor material can be epitaxially grown using a PECVD process at a temperature of about 500° C. or below. For example, as described with reference to FIGS. 9B, 10B, 13B, and 14B, the p-type or n-type semiconductor material can be epitaxially grown using processes 900B, 1000B, 1300B, or 1400B.

Referring to FIGS. 9B and 37, in some embodiments, the p-type or n-type semiconductor material can be epitaxially grown in opening 3610 and on vertical channel layer 3442 to form S/D region 3410a, using process 900B. The discussion of epitaxially growing p-type semiconductor material in S/D opening 2110 using process 900B in operation 1820 applies to epitaxially growing p-type semiconductor material in opening 3610 using process 900B in operation 3515, unless mentioned otherwise. The discussion of epitaxially growing n-type semiconductor material in S/D opening 2110 using process 900B in operation 1830 applies to epitaxially growing n-type semiconductor material in opening 3610 using process 900B in operation 3515, unless mentioned otherwise.

Referring to FIGS. 10B and 37, in some embodiments, the p-type or n-type semiconductor material can be epitaxially grown in opening 3610 and on vertical channel layer 3442 to form S/D region 3410a, using process 1000B. The discussion of epitaxially growing p-type semiconductor material in S/D opening 2110 using process 1000B in operation 1820 applies to epitaxially growing p-type semiconductor material in opening 3610 using process 1000B in operation 3515, unless mentioned otherwise. The discussion of epitaxially growing n-type semiconductor material in S/D opening 2110 using process 1000B in operation 1830 applies to epitaxially growing n-type semiconductor material in opening 3610 using process 1000B in operation 3515, unless mentioned otherwise.

Referring to FIGS. 13B and 37, in some embodiments, the p-type or n-type semiconductor material can be epitaxially grown in opening 3610 and on vertical channel layer 3442 to form S/D region 3410a, using process 1300B. The discussion of epitaxially growing p-type semiconductor material in S/D opening 2110 using process 1300B in operation 1820 applies to epitaxially growing p-type semiconductor material in opening 3610 using process 1300B in operation 3515, unless mentioned otherwise. The discussion of epitaxially growing n-type semiconductor material in S/D opening 2110 using process 1300B in operation 1830 applies to epitaxially growing n-type semiconductor material in opening 3610 using process 1300B in operation 3515, unless mentioned otherwise.

Referring to FIGS. 14B and 37, in some embodiments, the p-type or n-type semiconductor material can be epitaxially grown in opening 3610 and on vertical channel layer 3442 to form S/D region 3410a, using process 1400B. The discussion of epitaxially growing p-type semiconductor material in S/D opening 2110 using process 1400B in operation 1820 applies to epitaxially growing p-type semiconductor material in opening 3610 using process 1400B in operation 3515, unless mentioned otherwise. The discussion of epitaxially growing n-type semiconductor material in S/D opening 2110 using process 1400B in operation 1830 applies to epitaxially growing n-type semiconductor material in opening 3610 using process 1400B in operation 3515, unless mentioned otherwise.

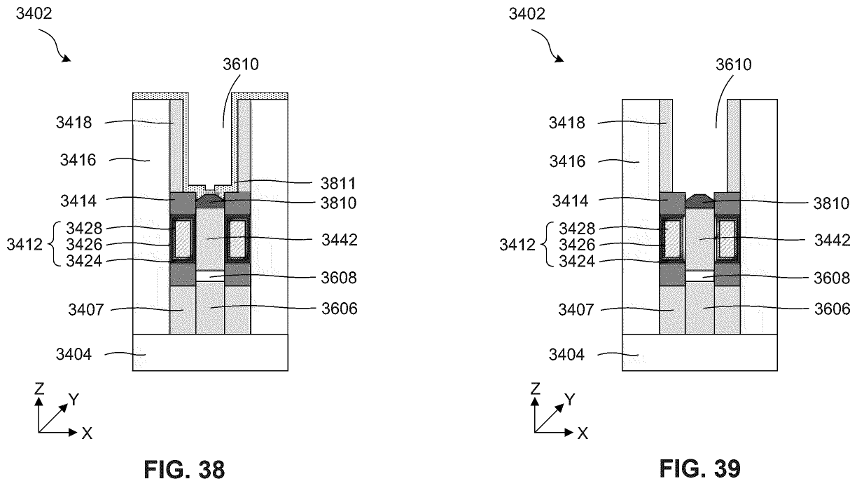

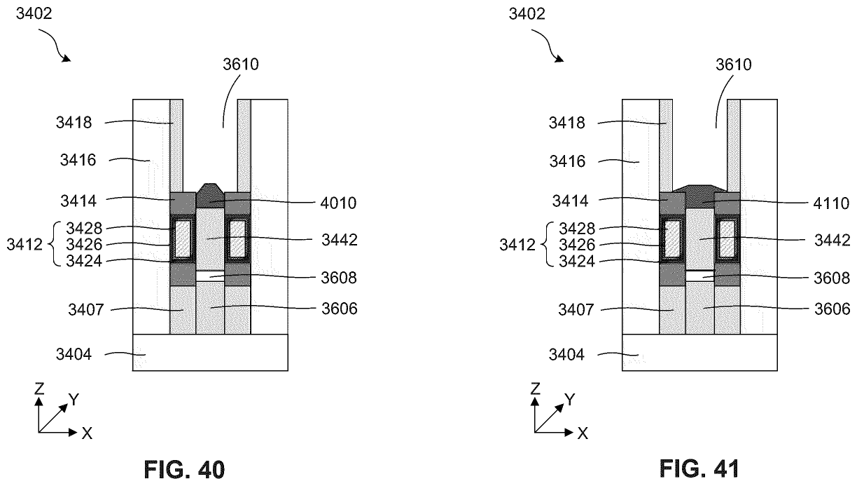

In some embodiments, forming S/D region 3410a using process 1000B, 1300B, or 1400B can include multiple gas flow cycles. In some embodiments, after the first phase of the first gas flow cycle of process 1000B, 1300B, or 1400B is completed, S/D region 3810 can be formed in opening 3610 and on vertical channel layer 3442, and an amorphous layer 3811 can be formed on exposed dielectric surfaces of gate spacer 3414, ILD layers 3418, and STI regions 3416, as shown in FIG. 38. In some embodiments, after the second phase of the first gas flow cycle of process 1000B, 1300B, or 1400B is completed, amorphous layer 3811 can be removed, as shown in FIG. 39. In some embodiments, after the second gas flow cycle of process 1000B, 1300B, or 1400B is completed, S/D region 4010 having a greater volume than that of S/D region 3810 can be formed in opening 3610, as shown in FIG. 40. In some embodiments, after the third gas flow cycle of process 1000B, 1300B, or 1400B is completed, S/D region 4110 having a greater volume than that of S/D region 4010 can be formed in opening 3610, as shown in FIG. 41 In some embodiments, after the multiple gas flow cycles of process 1000B, 1300B, or 1400B are completed at time T₂, S/D region 3410a can be completely formed in opening 3610, as shown in FIG. 37.

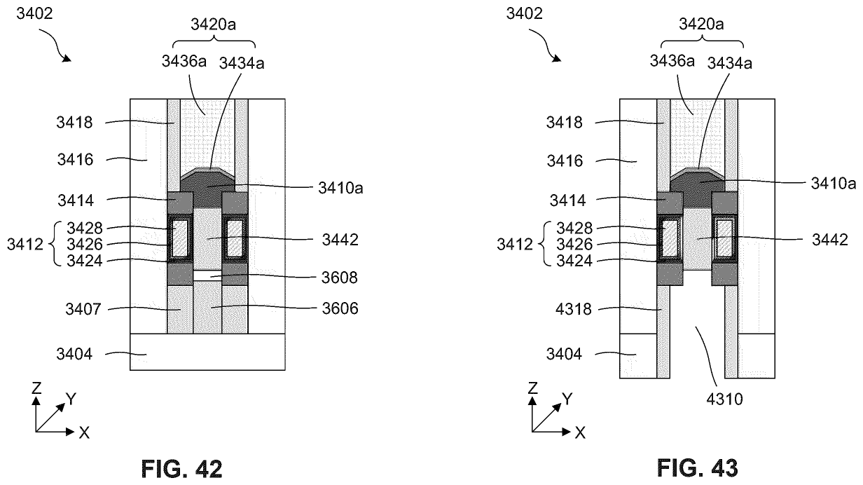

Referring to FIG. 35, in operation 3520, a first contact structure is formed on the first S/D region. For example, as described with reference to FIG. 42, front-side S/D contact structure 3420a is formed on front-side surface of S/D region 3410a. In some embodiments, the formation of front-side S/D contact structure 3420a can include sequential operations of (i) forming silicide layer 3434a on the front-side surface of S/D region 3410a and (ii) forming contact plug 3436a on silicide layer 3434a, as shown in FIG. 42.

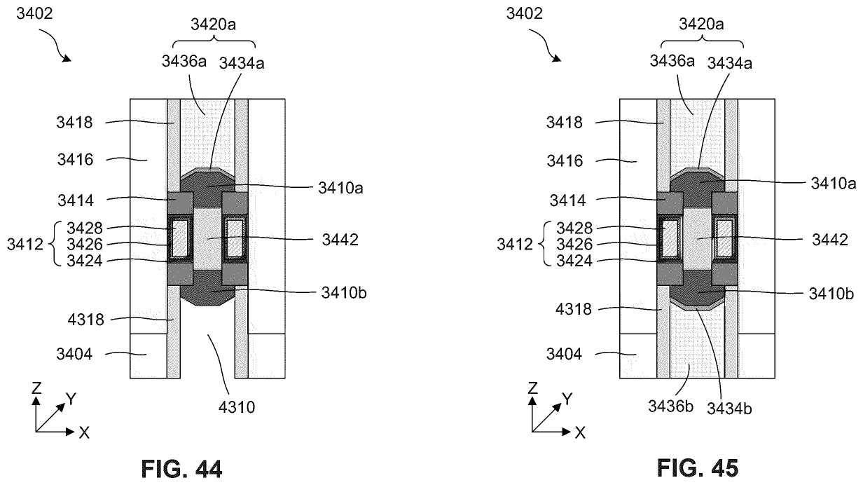

Referring to FIG. 35, in operation 3525, a second S/D region is formed on a back end of the vertical channel layer. For example, as described with reference to FIGS. 43 and 44, S/D region 3410b is formed on a back end of vertical channel layer 3442. In some embodiments, forming S/D region 3410b can include sequential operations of (i) forming an opening 4310 to expose the back end of vertical channel layer 3442 and (ii) epitaxially growing the p-type or n-type semiconductor material in opening 4310 and on the back end of vertical channel layer 3442, as shown in FIG. 44.

In some embodiments, forming opening 4310 can include sequential operations of (i) removing a portion of substrate 3404 from a back side to expose dielectric layer 3407 and vertical structure 3606, (ii) removing dielectric layer 3407, vertical structure 3606, and SiGe layer 3608 to form opening 4310, and (iii) forming ILD layers 4318 on side surfaces of STI regions 3416, as shown in FIG. 43.

In some embodiments, epitaxially growing the p-type or n-type semiconductor material in opening 4310 and on the back end of vertical channel layer 3442 can include the same or similar operations as described in operation 3515 with reference to FIGS. 37-41 for forming S/D region 3410a on the front end of vertical channel layer 3442.

Referring to FIG. 35, in operation 3530, a second contact structure is formed on the second S/D region. For example, as described with reference to FIG. 45, back-side S/D contact structure 3420b is formed on the back-side surface of S/D region 3410b. In some embodiments, forming back-side S/D contact structure 3420b on the back-side surface of S/D region 3410b can include the same or similar operations as described in operation 3520 with reference to FIG. 42 for forming front-side S/D contact structure 3420a on the front-side surface of S/D region 3410a.

The present disclosure provides example methods (e.g., methods 200, 1800, and 3500) for forming S/D regions or epitaxial regions in FETs (e.g., finFET 100, CFET 1700, or VFET 3402) using a PECVD process at a temperature of about 500° C. or below, with etch selectivity of etching processes greater than about 6. In some embodiments, the method can include a deposition process and an etching process performed in-situ in a PECVD chamber. The method can be used to selectively grow semiconductor materials of monocrystalline form in openings (e.g., S/D openings 710, 2110, 3610) with CD less than 30 nm and AR greater than 5, while adequately preventing the formation of nodules and clogs on dielectric surfaces (e.g., gate spacers 514 or inner spacers 1748). In some embodiments, the method can include providing a plasma, an etching gas, and a precursor gas in the PECVD chamber to form undoped S/D regions in the openings. In some embodiments, the method can further include providing a dopant precursor gas to form p-type or n-type S/D regions in the openings. In some embodiments, the method can further include controlling a plasma condition, a flow rate of the etching gas (e.g., etching gas flow rate 1304), a flow rate of the precursor gas (e.g., precursor gas flow rate 1006), a flow rate of the dopant precursor gas (e.g., dopant precursor gas flow rate 1010) or a combination thereof.

In some embodiments, the plasma can form radicals of the precursor gas and/or the etching gas during the deposition process and/or the etching process. And, as the radicals are highly reactive, the use of plasma can increase the deposition rate and/or the etching rate during the deposition process and/or the etching process at low temperatures (e.g., at a temperature of about 500° C. to about 20° C., at a temperature of about 400° C. or below, or at a temperature of about 400° C. to about 20° C.). Also, due to the highly reactive radicals of the etching gas, additional ex-situ etching processes can be eliminated from the fabrication process of S/D regions or epitaxial regions in the FETs. Thus, the use of plasma during the deposition process and/or the etching process can decrease the time and cost of fabricating the S/D regions or epitaxial regions in the FETs.

In some embodiments, controlling the plasma condition, the flow rate of the etching gas, the flow rate of the precursor gas, and/or the flow rate of the dopant precursor gas can selectively grow semiconductor materials of monocrystalline form in openings with CD less than about 30 nm and AR greater than about 5, while adequately preventing the formation of defective amorphous semiconductor regions in the S/D regions or epitaxial regions and the formation of nodules and clogs on side surfaces of dielectric layers adjacent to the S/D regions or epitaxial regions in the FETs. Thus, the S/D regions or epitaxial regions formed in the FETs by the example methods can be formed with improved qualities, such as lower resistivity at lower temperatures compared to S/D regions or epitaxial regions formed by other epitaxial processes.

In some embodiments, a method includes forming a fin structure on a substrate, forming a polysilicon structure on the fin structure, removing a portion of the fin structure adjacent to the polysilicon structure to form an opening, and forming a S/D region in the opening. The forming the S/D region includes exposing the fin structure in the opening to a first flow rate of a precursor gas during a first phase of a gas flow cycle, a second flow rate of the precursor gas during a second phase of the gas flow cycle, an etching gas during the gas flow cycle, and a plasma during the gas flow cycle. The first flow rate is higher than the second flow rate. The exposing the fin structure in the opening to the precursor gas, the etching gas, and the plasma is performed in an in-situ process.

In some embodiments, a method includes forming a fin structure on a substrate, forming a dielectric layer on the fin structure, forming an opening in the fin structure and through the dielectric layer, and epitaxially growing a semiconductor layer on the fin structure in the opening. The epitaxially growing the semiconductor layer includes performing a deposition process using a first flow rate of a precursor gas during a first phase of a gas flow cycle and a second flow rate of the precursor gas during a second phase of the gas flow cycle, performing an etching process using a first flow rate of an etching gas during the first phase of the gas flow cycle and a second flow rate of the etching gas during a second phase of the gas flow cycle, and performing a plasma process during the gas flow cycle. The first flow rate of the precursor gas is higher than the first flow rate of the etching gas and the second flow rate of the precursor gas is lower than the second flow rate of the etching gas.

In some embodiments, a method includes forming a first superlattice structure on a substrate, forming an isolation layer on the first superlattice structure, forming a second superlattice structure on the isolation layer, forming an opening through the second superlattice structure, the isolation layer, and the first superlattice structure, and forming a S/D region in the opening and in contact with the first superlattice structure. The forming the S/D region includes performing a deposition process using a first flow rate of a precursor gas during a first phase of a gas flow cycle and a second flow rate of the precursor gas during a second phase of the gas flow cycle, performing a doping process using a first flow rate of a dopant precursor gas during the first phase of the gas flow cycle and a second flow rate of the dopant precursor gas during the second phase of the gas flow cycle, generating a plasma during the second phase of the gas flow cycle, and terminating the plasma during the first phase of the gas flow cycle. The first flow rate of the precursor gas is higher than the second flow rate of the precursor gas. The first flow rate of the dopant precursor gas is higher than the second flow rate of the dopant precursor gas.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin structure on a substrate;
forming a polysilicon structure on the fin structure;
removing a portion of the fin structure adjacent to the polysilicon structure to form an opening; and
forming a source/drain (S/D) region in the opening comprising exposing the fin structure in the opening to:
a first flow rate of a precursor gas during a first phase of a gas flow cycle;
a second flow rate of the precursor gas during a second phase of the gas flow cycle, wherein the first flow rate is higher than the second flow rate;
an etching gas during the gas flow cycle; and
a plasma during the gas flow cycle,
wherein exposing the fin structure in the opening to the precursor gas, the etching gas, and the plasma is performed in an in-situ process.

2. The method of claim 1, wherein exposing the fin structure in the opening to the etching gas comprises exposing the fin structure in the opening to a flow rate of the etching gas that is higher than the first flow rate of the precursor gas.

3. The method of claim 1, wherein exposing the fin structure in the opening to the etching gas comprises:
maintaining a first flow rate of the etching gas during the first phase of the gas flow cycle;
maintaining a second flow rate of the etching gas during the second phase of the gas flow cycle, wherein the first flow rate is lower than the second flow rate.

4. The method of claim 1, wherein exposing the fin structure in the opening to the etching gas comprises:
exposing, during the first phase of the gas flow cycle, the fin structure in the opening to a first flow rate of the etching gas that is lower than the first flow rate of the precursor gas;
exposing, during the second phase of the gas flow cycle, the fin structure in the opening to a second flow rate of the etching gas that is higher than the second flow rate of the precursor gas.

5. The method of claim 1, wherein forming the S/D region further comprises:
exposing the fin structure in the opening to a first flow rate of a dopant precursor gas during the first phase of the gas flow cycle; and
exposing the fin structure in the opening to a second flow rate of the dopant precursor gas during the second phase of the gas flow cycle, wherein the first flow rate of the dopant precursor gas is higher than the second flow rate of the dopant precursor gas.

6. The method of claim 1, wherein exposing the fin structure in the opening to the plasma comprises:
generating the plasma during the second phase of the gas flow cycle; and
terminating the plasma during the first phase of the gas flow cycle.

7. The method of claim 1, wherein exposing the fin structure in the opening to the plasma comprises generating the plasma during the first and second phases of the gas flow cycle.

8. The method of claim 1, wherein exposing the fin structure in the opening to the precursor gas, the etching gas, and the plasma is performed at a temperature of about 500° C. or below.

9. The method of claim 1, wherein forming the S/D region comprises epitaxially growing a semiconductor material and removing an amorphous material on a dielectric side surface of the opening.

10. The method of claim 1, wherein forming the S/D region further comprises controlling a ratio of the first flow rate of the precursor gas and a flowrate of the etching gas to be about 50000:1 to about 1:50000.

11. A method, comprising:
forming a fin structure on a substrate;
forming a dielectric layer on the fin structure;
forming an opening in the fin structure and through the dielectric layer; and
epitaxially growing a semiconductor layer on the fin structure in the opening, comprising:
performing a deposition process using a first flow rate of a precursor gas during a first phase of a gas flow cycle and a second flow rate of the precursor gas during a second phase of the gas flow cycle;
performing an etching process using a first flow rate of an etching gas during the first phase of the gas flow cycle and a second flow rate of the etching gas during a second phase of the gas flow cycle, wherein the first flow rate of the precursor gas is higher than the first flow rate of the etching gas and wherein the second flow rate of the precursor gas is lower than the second flow rate of the etching gas; and
performing a plasma process during the gas flow cycle.

12. The method of claim 11, wherein performing the deposition process, the etching process, and the plasma process is an in-situ process.

13. The method of claim 11, wherein the deposition process, the etching process, and the plasma process are performed at a temperature of about 500° C. or below.

14. The method of claim 11, wherein performing the plasma process comprises:
generating a plasma during the second phase of the gas flow cycle; and
terminating the plasma process during the first phase of the gas flow cycle.

15. The method of claim 11, wherein epitaxially growing the semiconductor layer further comprises performing a doping process using a first flow rate of a dopant precursor gas during the first phase of the gas flow cycle and a second flow rate of the dopant precursor gas during the second phase of the gas flow cycle, and
wherein the first flow rate the dopant precursor gas is higher than the second flow rate of the dopant precursor gas.

16. A method, comprising:
forming a first superlattice structure on a substrate;
forming an isolation layer on the first superlattice structure;
forming a second superlattice structure on the isolation layer;
forming an opening through the second superlattice structure, the isolation layer, and the first superlattice structure; and
forming a source/drain (S/D) region in the opening and in contact with the first superlattice structure, comprising:
performing a deposition process using a first flow rate of a precursor gas during a first phase of a gas flow cycle and a second flow rate of the precursor gas during a second phase of the gas flow cycle, wherein the first flow rate of the precursor gas is higher than the second flow rate of the precursor gas;
performing a doping process using a first flow rate of a dopant precursor gas during the first phase of the gas flow cycle and a second flow rate of the dopant precursor gas during the second phase of the gas flow cycle, wherein the first flow rate of the dopant precursor gas is higher than the second flow rate of the dopant precursor gas;
generating a plasma during the second phase of the gas flow cycle; and
terminating the plasma during the first phase of the gas flow cycle.

17. The method of claim 16, wherein the first flow rate of the precursor gas is a non-zero value and the second flow rate of the precursor gas is zero.

18. The method of claim 16, wherein forming the S/D region further comprises performing an etching process using a first flow rate of an etching gas during the first phase of the gas flow cycle and a second flow rate of the etching gas during a second phase of the gas flow cycle; and
wherein the first flow rate of the etching gas is zero and the second flow rate of the etching gas is a non-zero value.

19. The method of claim 16, wherein forming the S/D region further comprises forming a p-type epitaxial region in the opening.

20. The method of claim 16, further comprising forming an n-type S/D region in the opening, on the S/D region, and in contact with the second superlattice structure.
